(19) United States
(12) Patent Application Publication
(10) Pub. No.: US 2026/0033187 A1
(43) Pub. Date: Jan. 29, 2026

(54) DISPLAY PANEL AND ELECTRONIC DEVICE INCLUDING THE SAME

(71) Applicant: SAMSUNG DISPLAY CO., LTD., Yongin-si (KR)

(72) Inventors: Minki Yang, Yongin-si (KR); Hyunae Park, Yongin-si (KR); Iljoo Kim, Yongin-si (KR); Minku Lee, Yongin-si (KR)

(21) Appl. No.: 19/277,608

(22) Filed: Jul. 23, 2025

(30) Foreign Application Priority Data
Jul. 23, 2024 (KR) 10-2024-0097506

(51) Int. Cl. H10K 59/131; H10K 59/121

(52) U.S. Cl. CPC H10K 59/131; H10K 59/1213

(57) ABSTRACT

A display panel includes a first pixel circuit including a first conductive pattern disposed on the substrate, a second conductive pattern disposed on the first conductive pattern and overlapping the first conductive pattern, a first semiconductor pattern disposed on the second conductive pattern, the first semiconductor pattern including a semiconductor layer of the driving transistor, a second semiconductor pattern disposed on a same layer as the first semiconductor pattern and spaced apart from the first semiconductor pattern, and a third conductive pattern disposed on the first semiconductor pattern and connecting the first semiconductor pattern to the second conductive pattern, wherein the first conductive pattern is electrically connected to the second semiconductor pattern, and a portion of the second semiconductor pattern overlaps a hold gate line extending in a first direction and electrically connected to the first pixel circuit.

### CROSS-REFERENCE TO RELATED APPLICATION

This application claims priority under 35 U.S.C. § 119 to Korean Patent Application No. 10-2024-0097506, filed on Jul. 23, 2024, in the Korean Intellectual Property Office, the disclosure of which is incorporated by reference herein in its entirety.

### TECHNICAL FIELD

The present disclosure relates to a display and, more specifically, to a display panel and an electronic device including the same.

### DISCUSSION OF THE RELATED ART

The use of display devices has rapidly expanded, with applications now ranging from mobile devices to wearable technology, automotive displays, and large-format signage. As display technologies evolve, there is a growing demand for high-resolution and improved image quality to meet the expectations of diverse industries and consumers.

To achieve high-resolution displays, a wide range of electronic components may be integrated into increasingly compact spaces. This poses significant technical challenges, including managing signal interference, ensuring efficient power usage, and maintaining device reliability. Addressing these challenges requires innovative design approaches for display panels, pixel circuits, and related components to optimize performance, minimize power consumption, and reduce production complexities.

### SUMMARY

A display panel includes a substrate, a first pixel circuit disposed on the substrate and including a driving transistor, and a light-emitting diode connected to the first pixel circuit. The first pixel circuit further includes a first conductive pattern disposed on the substrate, a second conductive pattern disposed on the first conductive pattern and overlapping the first conductive pattern, a first semiconductor pattern disposed on the second conductive pattern, the first semiconductor pattern including a semiconductor layer of the driving transistor, a second semiconductor pattern disposed on a same layer as the first semiconductor pattern and spaced apart from the first semiconductor pattern, and a third conductive pattern disposed on the first semiconductor pattern and connecting the first semiconductor pattern to the second conductive pattern. The first conductive pattern is electrically connected to the second semiconductor pattern, and a portion of the second semiconductor pattern overlaps a hold gate line extending in a first direction and electrically connected to the first pixel circuit.

The first conductive pattern and the second conductive pattern may be included in a hold capacitor of the first pixel circuit.

The display panel may further include a reference voltage line extending in the first direction and electrically connected to the first pixel circuit. A first end of the second semiconductor pattern may be electrically connected to the first conductive pattern, and a second end of the second semiconductor pattern may be electrically connected to the reference voltage line.

The first pixel circuit may further include a fourth conductive pattern disposed on a same layer as the third conductive pattern and spaced apart from the third conductive pattern, and the second semiconductor pattern may be electrically connected to the first conductive pattern through the fourth conductive pattern.

With respect to a thickness direction of the substrate, the hold gate line may be disposed between the first semiconductor pattern and the third conductive pattern.

The hold gate line may be disposed on a same layer as a gate electrode of the driving transistor.

The first pixel circuit may further include a third semiconductor pattern disposed on a same layer as the first semiconductor pattern and spaced apart from the first semiconductor pattern and a fifth conductive pattern connecting a gate electrode of the driving transistor to the third semiconductor pattern. The fifth conductive pattern may be disposed on a same layer as the third conductive pattern.

The display panel may further include a scan line extending in the first direction and electrically connected to the first pixel circuit and a data line extending in a second direction crossing the first direction and electrically connected to the first pixel circuit. A portion of the third semiconductor pattern may overlap a portion of the scan line, and an end of the third semiconductor pattern may be electrically connected to the data line.

In a plan view, the hold gate line may cross between the first semiconductor pattern and the third semiconductor pattern.

In a plan view, a portion of the hold gate line may overlap the fifth conductive pattern.

The first pixel circuit may further include a fourth semiconductor pattern disposed between the substrate and the first conductive pattern and a sixth conductive pattern connecting an end of the first semiconductor pattern to the fourth semiconductor pattern. The sixth conductive pattern may be disposed on a same layer as the third conductive pattern.

The first semiconductor pattern may include a material that is different from a material of the fourth semiconductor pattern.

The first semiconductor pattern may include an oxide semiconductor material, and the fourth semiconductor pattern may include a silicon semiconductor material.

The display panel may further include a first emission control line extending in the first direction and electrically connected to the first pixel circuit and a driving voltage line extending in the first direction or a second direction crossing the first direction and electrically connected to the first pixel circuit. A portion of the fourth semiconductor pattern may overlap the first emission control line, and an end of the fourth semiconductor pattern may be electrically connected to the driving voltage line.

In a plan view, the hold gate line may cross between the first semiconductor pattern and the fourth semiconductor pattern.

In a plan view, a portion of the hold gate line may overlap the sixth conductive pattern.

The first pixel circuit may further include a fifth semiconductor pattern disposed on a same layer as the first semiconductor pattern and spaced apart from the first semiconductor pattern, the third conductive pattern may include a central portion and a protrusion portion protruding from the central portion, and the protrusion portion of the third conductive pattern may be electrically connected to the fifth semiconductor pattern.

The display panel may further include a second emission control line extending in the first direction and electrically connected to the first pixel circuit. A portion of the fifth semiconductor pattern may overlap the second emission control line, and an end of the fifth semiconductor pattern may be electrically connected to the light-emitting diode.

In a plan view, the hold gate line may cross between the first semiconductor pattern and the fifth semiconductor pattern.

In a plan view, a portion of the hold gate line may overlap the protrusion portion of the third conductive pattern.

A display panel includes a substrate, a first pixel circuit disposed on the substrate, a hold gate line extending in a first direction and electrically connected to the first pixel circuit, and a light-emitting diode electrically connected to the first pixel circuit. The first pixel circuit includes a first transistor, a first connection electrode connecting the first transistor to the light-emitting diode, a hold capacitor including a first hold electrode and a second hold electrode opposite to the first hold electrode and electrically connected to the first connection electrode, and a second transistor electrically connected to the first hold electrode, and the hold gate line includes a gate electrode of the second transistor.

With respect to a thickness direction of the substrate, the second hold electrode may be disposed on the first hold electrode, a semiconductor layer of the first transistor may be disposed on the second hold electrode, and the first connection electrode may be disposed on the semiconductor layer of the first transistor.

With respect to the thickness direction of the substrate, the hold gate line may be disposed between the semiconductor layer of the first transistor and the first connection electrode.

The first pixel circuit may further include a third transistor connected between a data line and a gate electrode of the first transistor and a fourth transistor connected between a reference voltage line and the gate electrode of the first transistor.

The second transistor may be connected between the hold capacitor and the reference voltage line.

In a plan view, the hold gate line may cross between the first transistor and the third transistor.

The first pixel circuit may further include a second connection electrode connecting the gate electrode of the first transistor to a semiconductor layer of the second transistor, and a portion of the hold gate line may overlap the second connection electrode.

The second connection electrode may be disposed on a same layer as the first connection electrode and spaced apart from the first connection electrode.

The first pixel circuit may further include a fifth transistor connected between a driving voltage line and the first transistor and a sixth transistor connected between the first transistor and the light-emitting diode.

The hold gate line may further include a stem portion extending in the first direction and a branch portion protruding from the stem portion and extending in a second direction crossing the first direction.

The gate electrode of the second transistor may be formed in the branch portion of the hold gate line.

In a plan view, the stem portion of the hold gate line may cross between the first transistor and the fifth transistor.

The first connection electrode may be connected to a semiconductor layer of the sixth transistor, and a portion of the stem portion of the hold gate line may overlap the first connection electrode.

The first pixel circuit may further include a third connection electrode connecting a semiconductor layer of the first transistor to a semiconductor layer of the fifth transistor, and a portion of the stem portion of the hold gate line may overlap the third connection electrode.

The third connection electrode may be disposed on a same layer as the first connection electrode and spaced apart from the first connection electrode.

A semiconductor layer of the first transistor may be disposed on a different layer from a semiconductor layer of the fifth transistor.

The semiconductor layer of the first transistor may include an oxide semiconductor material, and the semiconductor layer of the fifth transistor may include a silicon-based semiconductor material.

The display panel may further include a second pixel circuit disposed on the substrate adjacent to the first pixel circuit in the first direction. The first transistor, the hold capacitor, and the second transistor of the first pixel circuit may be linearly symmetrical with a first transistor, a hold capacitor, and a second transistor of the second pixel circuit, respectively, with respect to a virtual straight line extending in a second direction crossing the first direction.

The display panel may further include a third pixel circuit disposed on the substrate adjacent to the second pixel circuit in the first direction. The first transistor, the hold capacitor, and the second transistor of the second pixel circuit may be linearly symmetrical with a first transistor, a hold capacitor, and a second transistor of the third pixel circuit, respectively, with respect to the virtual straight line extending in the second direction crossing the first direction.

The hold gate line may further include a stem portion extending in the first direction and a branch portion protruding from the stem portion and extending in the second direction. The branch portion of the hold gate line may include a first branch portion protruding toward the second transistor of the first pixel circuit and a second branch portion protruding toward the second transistor of the second pixel circuit and the second transistor of the third pixel circuit.

An electronic device includes a display panel and a lower cover forming an exterior shape and having an opening on a front surface thereof, the opening exposing a portion of the display panel. The display panel includes a substrate, a first pixel circuit disposed on the substrate and including a driving transistor, a hold gate line extending in a first direction and electrically connected to the first pixel circuit, and a light-emitting diode connected to the first pixel circuit. The first pixel circuit further includes a first conductive pattern disposed on the substrate, a second conductive pattern disposed on the first conductive pattern and overlapping the first conductive pattern, a first semiconductor pattern disposed on the second conductive pattern, the first semiconductor pattern including a semiconductor layer of the driving transistor, a second semiconductor pattern disposed on a same layer as the first semiconductor pattern and spaced apart from the first semiconductor pattern, and a third conductive pattern disposed on the first semiconductor pattern and connecting the first semiconductor pattern to the second conductive pattern. The first conductive pattern is electrically connected to the second semiconductor pattern, and a portion of the second semiconductor pattern overlaps the hold gate line.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a perspective view of an electronic device according to an embodiment;

FIG. 2 is an exploded perspective view of an electronic device according to an embodiment;

FIG. 3 is a block diagram of an electronic device according to an embodiment;

FIG. 4 is a schematic plan view of a display panel according to an embodiment;

FIG. 5 is a schematic side view of a display panel according to an embodiment;

FIG. 6 is a schematic plan view of a display panel according to an embodiment;

FIG. 7 is a schematic plan view of pixel circuits of a display panel according to an embodiment;

FIG. 8 is a cross-sectional view of a display panel according to an embodiment, taken along a line VIII-VIII′ of FIG. 6;

FIGS. 9 to 16 are plan views for showing a process of forming a pixel circuit of a display panel according to an embodiment;

FIG. 17 is an enlarged plan view of a portion of a display panel according to an embodiment;

FIG. 18 is a schematic plan view of pixel circuits of a display panel according to an embodiment;

FIGS. 19 to 26 are plan views for showing a process of forming a pixel circuit of a display panel according to an embodiment; and

FIG. 27 is an enlarged plan view of a portion of a display panel according to an embodiment.

### DETAILED DESCRIPTION

Reference will now be made in detail to embodiments, examples of which are illustrated in the accompanying drawings, wherein like reference numerals may refer to like elements throughout the specification and the drawings. In this regard, the present embodiments may have different forms and should not necessarily be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of having various modifications and alternative forms, embodiments thereof are shown by way of example in the drawings and will herein be described in detail. The effects and characteristics of the disclosure and methods of achieving the same will become apparent by referring to the embodiments described below in detail with reference to the drawings. However, the disclosure is not necessarily limited to the embodiments disclosed hereinafter and may be realized in various forms.

Hereinafter, embodiments of the disclosure will be described in detail by referring to the accompanying drawings. In descriptions with reference to the drawings, the same reference numerals may be given to elements that are the same or substantially the same and to the extent that an element is not described in detail with respect to this figure, it may be understood that the element is at least similar to a corresponding element that has been described elsewhere within the present disclosure.

In the embodiments described hereinafter, the terms “first,” “second,” etc. are used to distinguish an element from another and are not used as a restrictive sense.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being formed “on” another layer, area, or element, it can be directly or indirectly formed on the other layer, region, or element. That is, for example, intervening layers, regions, or elements may be present.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

When a certain embodiment may be implemented differently, a specific process order may be performed differently from the described order. For example, two consecutively described processes may be performed substantially at the same time or performed in an order opposite to the described order.

In the embodiments hereinafter, it will be understood that when an element, an area, or a layer is referred to as being connected to another element, area, or layer, it can be directly or indirectly connected to the other element, area, or layer. For example, it will be understood in this specification that when an element, an area, or a layer is referred to as being in contact with or being electrically connected to another element, area, or layer, it can be directly or indirectly in contact with or electrically connected to the other element, area, or layer.

Embodiments of the present disclosure relate to a detailed structure and arrangement of a display panel and its associated components, aimed at improving the functionality and efficiency of high-resolution displays. This may be accomplished by the introduction of an innovative pixel circuit design including a pixel circuit structure with a driving transistor, multiple transistors, and capacitors configured to enhance display performance by minimizing power loss and optimizing signal transmission.

Various semiconductor materials, such as oxide and silicon-based layers, may be utilized to achieve high carrier mobility and low leakage current. These materials may be layered to increase reliability and reduce interference.

Symmetry in the arrangement of pixel circuits may be utilized to maintain consistency in signal processing and display quality.

Integrating flexible and rigid components may be used to adapt the display for diverse applications, such as smartphones, wearable devices, and automotive displays.

This approach may target better visual quality, reduced energy consumption, and enhanced flexibility in design and functionality.

According to various approaches, power loss in the display pixel design may be minimized by the use of dual-gate driving transistors. For example, the driving transistor (T1) may feature a dual-gate structure, including a lower gate electrode connected to a capacitor (Chd) and a node electrode (N2). This configuration may ensure stable voltage levels and reduces signal interference, which minimizes power dissipation.

The transistors may employ oxide semiconductor materials (e.g., InGaZnO or InSnZnO), which offer high carrier mobility and low leakage current. This may reduce power loss during operation and enhances efficiency in current flow.

Capacitors such as the hold capacitor (Chd) and storage capacitor (Cst) may be strategically placed to stabilize voltages and reduce transient energy losses, preventing unnecessary current consumption.

Symmetrical and modular arrangements of pixel circuits may minimize signal overlap and routing inefficiencies, ensuring that power is directed efficiently without unnecessary dissipation.

The pixel circuit may include emission control transistors (T5 and T6) that regulate the flow of current to the light-emitting elements. This precise control may minimize power waste by allowing current to flow only during active emission periods.

The use of capacitive coupling between transistors and voltage lines may reduce signal noise and power loss by stabilizing the voltage levels across the circuit.

These measures may collectively enhance the power efficiency of the display panel, making it suitable for high-performance and energy-sensitive applications

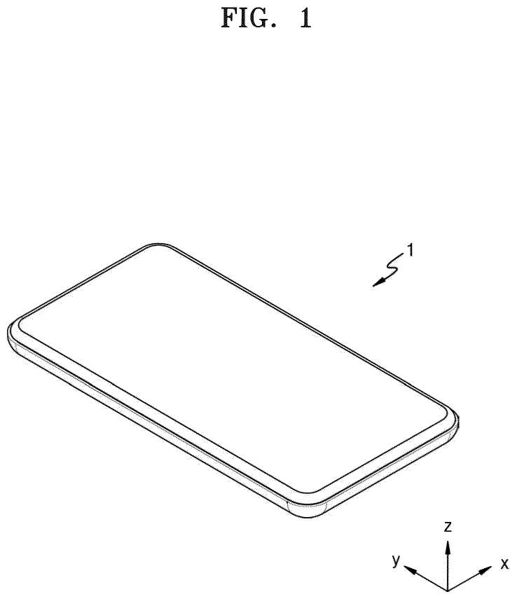

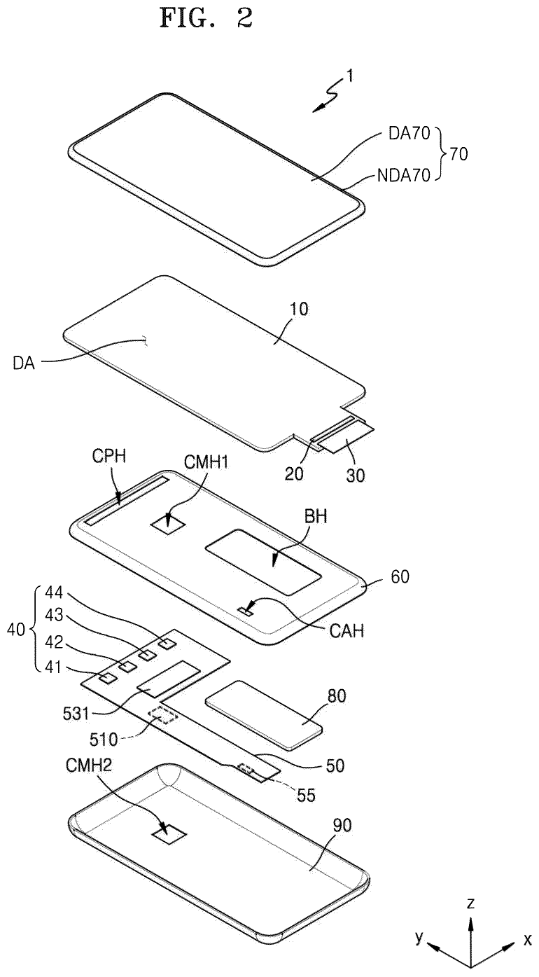

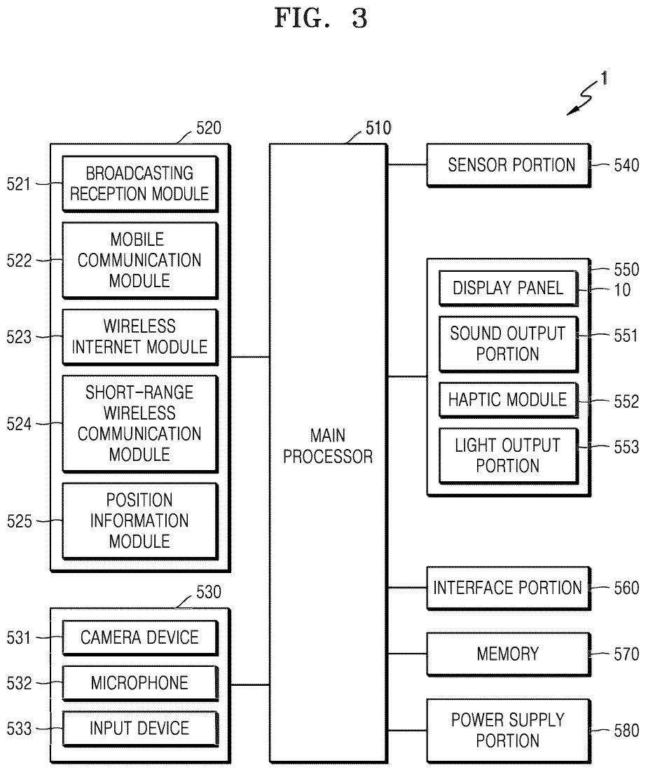

FIG. 1 is a perspective view of an electronic device 1 according to an embodiment, FIG. 2 is an exploded perspective view of the electronic device 1 according to an embodiment, and FIG. 3 is a block diagram of the electronic device 1 according to an embodiment.

Referring to FIGS. 1 and 2, the electronic device 1, according to an embodiment, may display a motion image or a static image and may be used as a display screen not only of portable electronic devices, such as a mobile phone, a smartphone, a tablet computer, a mobile communication terminal, an electronic notebook, an electronic book, a portable multimedia player (PMP), a navigation device, and an ultra-mobile PC (UMPC), but also of various products, such as a television (TV), a notebook computer, a computer monitor, a signboard, such as a digital billboard, an Internet of things (IOT) device, etc. The electronic device 1, according to an embodiment, may be used for wearable devices, such as a smart watch, a watch phone, a glasses-type display, and a head-mounted display (HMD). The electronic device 1, according to an embodiment, may be used as: a center information display (CID) on a gauge of a vehicle or a center fascia or a dashboard of a vehicle; a room mirror display substituting a side-view mirror of a vehicle; or a display disposed on a rear surface of a front seat, as an entertainment device for a backseat of a vehicle.

In FIGS. 1 and 2, it is illustrated, for convenience of explanation, that the electronic device 1, according to an embodiment, is used as a smartphone. The electronic device 1, according to an embodiment, may include a cover window 70, a display panel 10, a data driver 20, a display circuit board 30, components 40, a bracket 60, a main circuit board 50, a battery 80, and a lower cover 90.

In a plan view of this specification, “upper,” “lower,” “right,” and “left” positions indicate positions of the display panel 10 viewed in a direction perpendicular to the display panel 10. For example, the “upper” position may indicate a +y direction, the “lower” position may indicate a-y direction, the “right” position may indicate a +x direction, and the “left” position may indicate a-x direction.

The electronic device 1 may have a rectangular shape in a plan view. For example, the electronic device 1 may have a rectangular planar shape having a pair of short side extending in an x direction and a pair of long side extending in a y direction as illustrated in FIG. 1. A corner at which the short side in the x direction and the long side in the y direction meet each other may be curved to have a predetermined curvature or may be right-angled. The planar shape of the electronic device 1 is not necessarily limited to the rectangular planar shape and may include other shapes, such as a polygonal shape, an oval shape, or an amorphous shape.

The cover window 70 may be disposed above the display panel 10 to cover an upper surface of the display panel 10. Accordingly, the cover window 70 may protect the upper surface of the display panel 10.

The cover window 70 may include a transmissive cover portion DA70 corresponding to the display panel 10 and a light-blocking cover portion NDA70 surrounding the transmissive cover portion DA70. The light-blocking cover portion NDA70 may include a non-transparent material (for example, a colored non-transparent material) blocking light. The light-blocking cover portion NDA70 may include a pattern which may be shown to a user when an image is not displayed.

The display panel 10 may be disposed below the cover window 70. The display panel 10 may overlap the transmissive cover portion DA70 of the cover window 70.

The display panel 10 may include a display area DA. The display area DA may be an area where an image is displayed and may include an area (hereinafter, a component area) transmitting light emitted from the components 40 disposed below the display panel 10. The component may include a sensor using visible rays, infrared rays, sound, etc. and a camera.

The display panel 10 may include a light-emitting display panel including a light-emitting diode. The light-emitting diode may include an organic light-emitting diode (OLED) including an organic emission layer. According to some embodiments, the light-emitting diode may include an inorganic light-emitting diode including an inorganic material. The inorganic light-emitting diode may include a PN junction diode including inorganic semiconductor-based materials. When a voltage is applied to the PN junction diode in a normal direction, holes and electrons may be injected into the PN junction diode and energy generated by recombination of the holes and the electrons may be converted into light energy, and thus, light of a certain color may be emitted. The inorganic light-emitting diode described above may have a width of several to hundreds of micrometers, and according to some embodiments, may be referred to as a micro light-emitting diode (LED).

The display panel 10 may include a rigid display panel that is rigid and is not easily bent or a flexible display panel that is flexible and is easily bent, folded, or rolled to a noticeable extent without cracking or otherwise sustaining damage. For example, the display panel 10 may include a foldable display panel which may be folded and unfolded, a curved display panel having a curved display surface, a bent display panel including bent portions excluding a display surface, a rollable display panel which may be rolled or unrolled, or a stretchable display panel which may be stretched.

The display panel 10 may include a transparent display panel, which is realized to be transparent so that an object or a background disposed at a lower surface of the display panel 10 may be seen at an upper surface of the display panel 10. Alternatively, the display panel 10 may include a reflective display panel configured to reflect an object or a background at the upper surface of the display panel 10.

The data driver 20 may be disposed on the display panel 10 as an integrated circuit (IC). According to an embodiment, the data driver 20 may be disposed on the display circuit board 30.

The display circuit board 30 may be attached at one side of the display panel 10. The display circuit board 30 may include a flexible printed circuit board (FPCB) which is bendable, a rigid printed circuit board (RPCB) which is rigid and not easily bent, or a complex printed circuit board including both of an FPCB and an RPCB.

According to an embodiment, a touch sensor driver may be disposed on the display circuit board 30. The touch sensor driver may be formed as an IC. The touch sensor driver may be attached onto the display circuit board 30. The touch sensor driver may be electrically connected to touch electrodes of a touch screen layer of the display panel 10 through the display circuit board 30.

The touch screen layer of the display panel 10 may sense a user's touch input by using at least one of various touch methods, such as a resistive layer method, a capacitance method, etc. For example, when the touch screen layer of the display panel 10 senses a user's touch input through a capacitance method, the touch sensor driver may determine whether or not there is a user's touch input by applying driving signals to driving electrodes from among the touch electrodes and may sensing, through sensing electrodes from among the touch electrodes, voltages charged to mutual capacitances (hereinafter, referred to as “mutual capacities”) between the driving electrodes and the sensing electrodes. The user's touch input may include a contact touch and a proximity touch. The contact touch may indicate a direct contact of a finger of a user or an object, such as a pen, or the like, with the cover window 70 disposed on the touch screen layer. The proximity touch may indicate a state in which a finger of a user or an object, such as a stylus/pen, or the like, is positioned adjacent to but spaced apart from the cover window 70, like hovering. The touch sensor driver may transmit sensor data to a main processor 510 according to the sensed voltages, and the main processor 510 may analyze the sensor data to calculate a touch coordinate in which the touch input has occurred.

A controller configured to supply driving voltages to drive pixels of the display panel 10, a gate driver, and the data driver 20 may be disposed on the display circuit board 30.

The bracket 60 for supporting the display panel 10 may be disposed below the display panel 10. The bracket 60 may include plastic, metal, or both plastic and metal. In the bracket 60, a first camera hole CMH1 into which a camera device 531 is inserted, a battery hole BH in which the battery 80 is disposed, and a cable hole CAH through which a cable connected to the display circuit board 30 passes, may be formed. In the bracket 60, a component hole CPH overlapping the display panel 10 may be provided. The component hole CPH may overlap the components 40 of the main circuit board 50 in a third direction (a z direction). According to an embodiment, the display area DA of the display panel 10 may overlap the components 40 of the main circuit board 50 in the third direction (the z direction). According to an embodiment, the component hole CPH might not be formed in the bracket 60.

According to an embodiment, the components 40 may include first to fourth components 41, 42, 43, and 44 overlapping the display panel 10. Each of the first to fourth components 41 to 44 may include a proximity sensor, an illumination sensor, an iris sensor, a facial recognition sensor, or a camera (or an image sensor). The proximity sensor using infrared light may sense an object disposed near to an upper surface of the electronic device 1, and the illumination sensor may sense a brightness of light incident onto the upper surface of the electronic device 1. Also, the iris sensor may capture an image of a human iris on the upper surface of the electronic device 1, and the camera may capture an image of an object disposed on the upper surface of the electronic device 1. The components 40 are not necessarily limited to the proximity sensor, the illumination sensor, the iris sensor, the facial recognition sensor, and the camera and may include various sensors described below.

The main circuit board 50 and the battery 80 may be disposed below the bracket 50. The main circuit board 50 may include a printed circuit board or an FPCB.

The main circuit board 50 may include the main processor 510, the camera device 531, a main connector 55, and the components 40. The main processor 510 may include an IC. The camera device 531 may be disposed at both an upper surface and a lower surface of the main circuit board 50 and each of the main processor 510 and the main connector 55 may be disposed at only one of the upper surface and the lower surface of the main circuit board 50.

The main processor 510 may control all functions of the electronic device 1. For example, the main processor 510 may output digital video data to the data driver 20 through the display circuit board 30, so that the display panel 10 may display an image. The main processor 510 may receive the sensor data from the touch sensor driver. The main processor 510 may determine whether or not there is a user's touch, according to the sensor data, and may perform an operation according to a direct touch or a proximity touch of a user. The main processor 510 may include an application processor, a central processing unit, or a system chip including an IC.

The camera device 531 may process an image frame, such as a static image or a motion image, obtained in a camera mode through an image sensor, and may output the processed image frame to the main processor 510. The camera device 531 may include at least one of a camera sensor (for example, a charge-coupled device (CCD) sensor, a complementary metal-oxide semiconductor (CMOS) sensor, etc.), a photo sensor (or an image sensor), and a laser sensor. The camera device 531 may be connected to the image sensor from among the components 40 overlapping the display area DA and may process an image input by the image sensor.

A cable 35 passing through the cable hole CAH of the bracket 60 may be connected to the main connector 55, and thus, the main circuit board 50 may be electrically connected to the display circuit board 30.

The main circuit board 50 may further include a wireless communicator 520, an input portion 530, a sensor portion 540, an output portion 550, an interface portion 560, a memory 570, and/or a power supply portion 580 illustrated in FIG. 3, in addition to the main processor 510, the camera device 531, and the main connector 55.

The wireless communicator 520 may include at least one of a broadcasting reception module 521, a mobile communication module 522, a wireless Internet module 523, a short-range wireless communication module 524, and a position information module 525.

The broadcasting reception module 521 may receive, from an external broadcasting management server, a broadcasting signal and/or broadcasting-related information, through a broadcasting channel. The broadcasting channel may include a satellite channel and a ground wave channel.

The mobile communication module 522 may transmit and receive a wireless signal to and from at least one of a base station, an external terminal, and a server on mobile communication networks established according to the technical standards for mobile communication or the communication methods (for example, a global system for mobile communication (GSM), code division multiple access (CDMA), CDMA 2000, enhanced voice-data optimized or enhanced voice-data only (EV-DO), wideband CDMA (WCDMA), high speed downlink packet access (HSDPA), high speed uplink packet access (HSUPA), long term evolution (LTE), LTE-advanced (LTE-A), etc.). The wireless signal may include a sound call signal, a video telephony call signal, or various forms of data according to transmission and reception of text/multimedia messages.

The wireless Internet module 523 may indicate a module for wireless Internet access. The wireless Internet module 523 may transmit and receive a wireless signal on a communication network according to the wireless Internet techniques. The wireless Internet techniques may include, for example, a wireless local area network (WLAN), wireless-fidelity (Wi-Fi), Wi-Fi direct, a digital living network alliance (DLNA), etc.

The short-range wireless communication module 524 may be used for short-range communication and may support short-range communication by using at least one of BLUETOOTH™, radio frequency identification (RFID), infrared data association (IrDA), an ultra wideband (UWB), ZIGBEE, near-field communication (NFC), Wi-Fi, Wi-Fi direct, and a wireless universal serial bus (USB). The short-range wireless communication module 524 may support wireless communication between the electronic device 1 and a wireless communication system, between the electronic device 1 and another electronic device, or between the electronic device 1 and a network on which another electronic device (or an external server) is located, through a short-range wireless communication network. The short-range wireless communication network may include a wireless personal area network. The other electronic device may include a wearable device which may exchange data (or which may be synchronized) with the electronic device 1.

The position information module 525 may include a module configured to obtain a position (or a current position) of the electronic device 1, and may include a global positioning system (GPS) module or a Wi-Fi module.

The input portion 530 may include an image input portion such as the camera device 531 configured to input an image signal, a sound input portion such as a microphone 532 configured to input a sound signal, and an input device 533 configured to receive information from a user.

The camera device 531 may process an image frame, such as a static image or a motion image, obtained through the image sensor in a video call mode or a photographing mode. The processed image frame may be displayed on the display panel 10 or stored in the memory 570.

The microphone 532 may process an external sound signal into electrical sound data. The processed sound data may be variously used according to a function performed (or an application executed) by the electronic device 1.

The main processor 510 may control operations of the electronic device 1 according to information input through the input device 533. The input device 533 may include a mechanical input device, such as a button, a dome switch, a jog wheel, a jog switch, etc. on a rear surface or a side surface of the electronic device 1 or a touch input device. The touch input device may be formed as the touch screen layer of the display panel 10.

The sensor portion 540 may include one or more sensors configured to sense at least one of information in the electronic device 1, information of an ambient environment surrounding the electronic device 1, and user information and to generate a sensing signal according to the sensed information. Based on the sensing signal, the main processor 510 may drive the electronic 1, control operations of the electronic device 1, or process data and perform functions or operations related to an application installed on the electronic device 1. The sensor portion 540 may include at least one of a proximity sensor, an illumination sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor, a battery gauge, an environmental sensor (for example, a barometer, a hygrometer, a thermometer, a radioactivity sensor, a heat sensing sensor, a gas sensing sensor, etc.), and a chemical sensor (for example, an electronic nose, a healthcare sensor, a biometric sensor, etc.).

The output portion 550 may generate an output related to a visual sense, an auditory sense, a haptic sense, or the like and may include at least one of the display panel 10, a sound output portion 551, a haptic module 552, and a light output portion 553.

The display panel 10 may display (output) information processed by the electronic device 1. For example, the display panel 10 may display execution screen information of an application driven by the electronic device 1 or user interface (UI) or graphics UI (GUI) information according to the execution screen information. The display panel 10 may include a display layer displaying an image and a touch screen layer configured to sense a touch input of a user. Thus, the display panel 10 may function as an example of the input device 533, which is configured to provide an input interface between the electronic device 1 and a user, and at the same time, as an example of the output portion 550, which is configured to provide an output interface between the electronic device 1 and the user.

The sound output portion 551 may output sound data which is received from the wireless communicator 520 or stored in the memory 570 in a call signal reception mode, a call mode, a recording mode, a voice recognition mode, a broadcasting reception mode, etc. The sound output portion 551 may output a sound signal related to a function (for example, a call signal reception sound, a message reception sound, etc.) performed by the electronic device 1. The sound output portion 551 may include a receiver and a speaker. At least one of the receiver and the speaker may include a sound generation device which is attached below the display panel 10 and vibrates the display panel 10 to output sound. The sound generation device may include a piezoelectric element or a piezoelectric actuator contracting or expanding according to an electrical signal or an exciter vibrating the display panel 10 by generating a magnetic force by using a voice coil.

The haptic module 552 may generate various haptic effects which may be felt by a user. The haptic module 552 may provide vibration to the user as a haptic effect. The haptic module 552 may transmit the haptic effects through direct contact. Also, the haptic module may allow a user to feel the haptic effects through sensation of muscles such as a finger, an arm, etc.

The light output portion 553 may use light of a light source to output a signal for notifying an occurrence of an event. Examples of the event occurring in the electronic device 1 may include message reception, call signal reception, an absent call, alarm, schedule notification, email reception, information reception through an application, etc. The signal output by the light output portion 553 may be realized via emission of light of a single color or a plurality of colors on a front surface or a rear surface of the electronic device 1. The outputting of the signal may be ended via sensing of the electronic device 1 with respect to user's identification of an event.

The interface portion 560 may serve as a path between the electronic device 1 and various types of external devices connected to the electronic device 1. The interface portion 560 may include at least one of a wired/wireless headset port, an external charger port, a wired/wireless data port, a memory card port, a port connecting a device including an identification module, an audio input/output (I/O) port, a video I/O port, and an earphone port. When an external device is connected to the interface portion 560, the electronic device 1 may perform an appropriate control operation related to the external device connected to the interface portion 560.

The memory 570 may store data supporting various functions of the electronic device 1. The memory 570 may store a plurality of applications driven in the electronic device 1 and data and instructions for operations of the electronic device 1. At least some of the plurality of applications may be downloaded from an external server through wireless communication. The memory 570 may store an application for an operation of the main processor 510 and may temporarily store input/output data, for example, data such as a phone book, a message, a static image, a motion image, etc. Also, the memory 570 may store haptic data for vibration of various patterns provided to the haptic module 552 and sound data related to various sounds provided to the sound output portion 551. The memory 570 may include a storage medium of at least one type from among a flash memory type, a hard disk type, a solid state disk (SSD) type, a silicon disk driver (SDD) type, a multimedia card micro type, a card type memory (for example, a secure digital (SD) or extreme digital (XD) memory, etc.) random-access memory (RAM), static RAM (SRAM), read-only memory (ROM), electrically erasable programmable ROM (EEPROM), programmable ROM (PROM), a magnetic memory, a magnetic disk, and an optical disk.

The power supply portion 580 may supply power to each component included in the electronic device 1 by receiving external power and internal power under control by the main processor 510. The power supply portion 580 may include the battery 80. Also, the power supply portion 580 may include a connection port, and the connection port may be provided as an example of the interface portion 560, to which an external charger supplying power for charging the battery is electrically connected. Alternatively, the power supply portion 580 may charge the battery 80 by using a wireless method, without using the connection port. The battery 80 might not overlap the main circuit board 50 in the third direction (the z direction). The battery 80 may overlap the battery hole BH of the bracket 60.

The lower cover 90 may be disposed below the main circuit board 50 and the battery 80. The lower cover 90 may be fastened and fixed to the bracket 60. The lower cover 90 may form the exterior shape of a lower surface of the electronic device 1. The lower cover 90 may include plastic, metal, or both plastic and metal.

A second camera hole CMH2 exposing a lower surface of the camera device 531 may be formed in the lower cover 90. The position of the camera device 531 and the positions of the first and second camera holes CMH1 and CMH2 corresponding to the camera device 531 might not necessarily be limited to the embodiment illustrated in FIGS. 1 and 2 and may be variously modified.

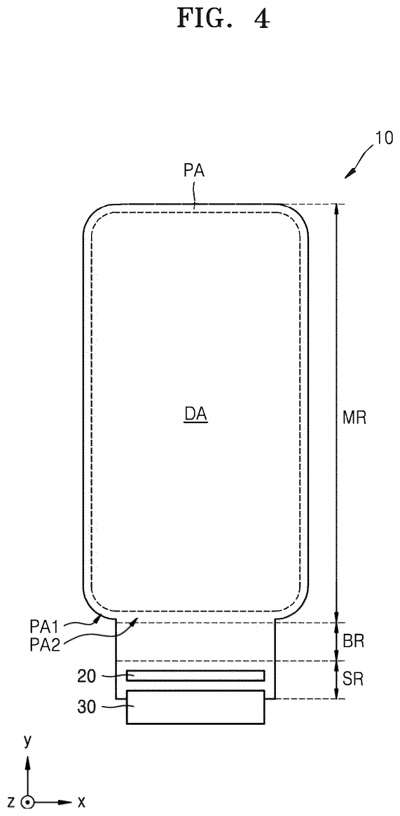

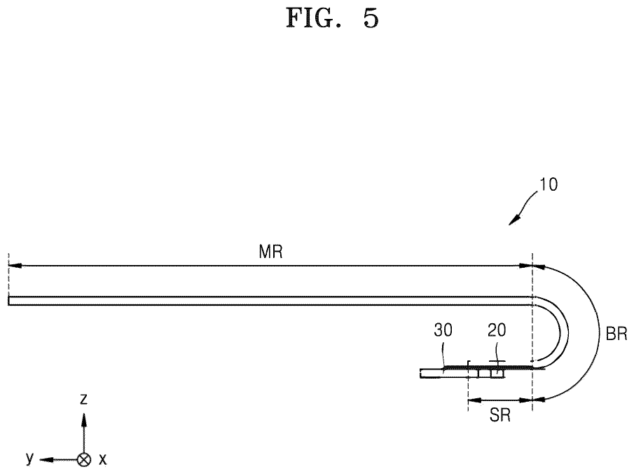

FIG. 4 is a schematic plan view of the display panel 10 according to an embodiment, and FIG. 5 is a schematic side view of the display panel 10 according to an embodiment.

The display panel 10 may include a display area DA and a peripheral area PA outside the display area DA. The display area DA may be an area for displaying an image, and a plurality of PX may be disposed in the display area DA. The display area DA may have various shapes, such as a circular shape, an oval shape, a polygonal shape, a shape of a predetermined figure, etc. For example, FIG. 4 illustrates that the display area DA may have an approximately rectangular shape with round edges.

The peripheral area PA may be disposed outside the display area DA. The peripheral area PA may include a first peripheral area PA1 surrounding at least a portion of the display area DA and a second peripheral area PA2 adjacent to one side of the display area DA and extending in a second direction (e.g., −y direction). A width of the second peripheral area PA2 in a first direction (e.g., an x-axis direction) may be less than a width of the display area DA in the first direction (e.g., the x-axis direction). Based on this structure, at least a portion of the second peripheral area PA2 may be easily bent.

The planar shape of the display panel 10 illustrated in FIG. 4 may be substantially the same as a shape of a substrate 100 included in the display panel 10. That the display panel 10 may include the display area DA and the peripheral area PA outside the display area DA may indicate that the substrate 100 may include the display area DA and the peripheral area PA outside the display area DA. Hereinafter, it is described, for convenience of explanation, that the substrate 100 may include the display area DA and the peripheral area PA.

The display panel 10 may include a main region MR, a bending region BR outside the main region MR, and a sub-region SR spaced apart from the main region MR with the bending region BR therebetween. The main region MR may be disposed at a side of the bending region BR, and the sub-region SR may be disposed at the other side of the bending region BR. As illustrated in FIG. 5, the display panel 10 may be bent in the bending region BR, and when viewed in a third direction (e.g., a z direction), at least a portion of the sub-region SR may overlap the main region MR. FIG. 5 illustrates that the display panel 10 may be bent. However, the disclosure is not necessarily limited thereto. According to an embodiment, the display panel 10 may include a foldable display panel, and the display area DA may be bent with respect to a bending axis crossing the display area DA. According to an embodiment, the display panel 10 might not be bent. The sub-region SR may be a non-display area.

The data driver 20 may be disposed in the sub-region SR of the display panel 10. The data driver 20 may be disposed on the display panel 10 as an IC. For example, the data driver 20 may include a data driving IC configured to generate a data signal.

The display circuit board 30 may be attached onto an end of the sub-region SR of the display panel 10. The display circuit board 30 may be electrically connected to the data driver 20, etc. through a pad of the sub-region SR of the display panel 10.

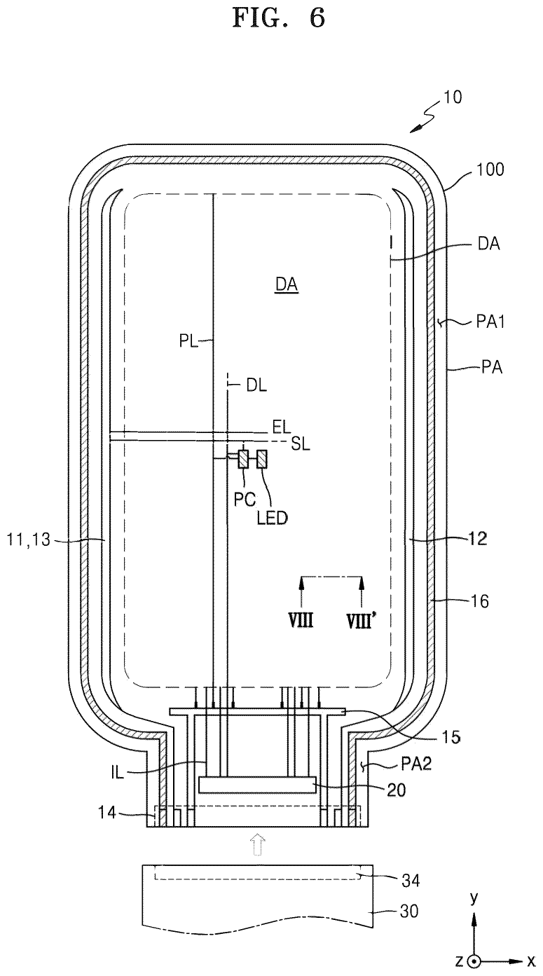

FIG. 6 is a schematic plan view of the display panel 10 according to an embodiment.

Referring to FIG. 6, the display panel 10 may include the substrate 100. Various elements included in the display panel 10 may be disposed on the substrate 100.

The substrate 100 may include glass, metal, or polymer resins. The substrate 100 may include, for example, polymer resins, such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a layered structure including two layers including the polymer resins described above and an inorganic layer disposed between the two layers.

Pixels may be disposed in the display area DA and the display area DA may provide an image by using light emitted from the pixels. Each pixel may include a light-emitting diode LED, and the light-emitting diode LED may be electrically connected to a pixel circuit PC. The pixel circuit PC and the light-emitting diode LED may be disposed in the display area DA.

Gate driving circuits (for example, a first scan driving circuit 11, a second scan driving circuit 12, an emission control driving circuit 13, a pad 14, a first power supply line 15, and a second power supply line 16) may be disposed in the peripheral area PA.

The first scan driving circuit 11 may provide a scan signal to the pixel circuit PC through a gate line SL. The second scan driving circuit 12 may be disposed at the opposite side to the first scan driving circuit 11 with the display area DA therebetween. Some of the pixel circuits PC disposed in the display area DA may be electrically connected to the first scan driving circuit 11, and the others may be connected to the second scan driving circuit 12. According to an embodiment, the second scan driving circuit 12 may be omitted.

The emission control driving circuit 13 may be disposed at a side of the first scan driving circuit 11 and may provide an emission control signal to a pixel PX through an emission control line EL. FIG. 6 illustrates that the emission control driving circuit 13 may be disposed at only one side of the display area DA. However, the disclosure is not necessarily limited thereto. According to an embodiment, the emission control driving circuits 13 may be disposed at both sides of the display area DA.

The pad 14 may be disposed in the second peripheral area PA2 of the substrate 100. The pad 14 might not be covered by an insulating layer and may be exposed and electrically connected to the display circuit board 30. A pad 34 of the display circuit board 30 may be electrically connected to the pad 14 of the display panel 10.

The display circuit board 30 may transmit a signal or power of a controller to the display panel 10. A control signal generated by the controller may be transmitted to each of the gate driving circuits through the display circuit board 30. Also, the controller may provide a driving voltage and a common voltage to each of the first and second power supply lines 15 and 16. The driving voltage may be provided to each pixel circuit PC through a driving voltage line PL connected to the first power supply line 15, and the common voltage may be provided to an opposite electrode of the light-emitting diode LED connected to the second power supply line 16. The first power supply line 15 may extend in a first direction (e.g., an x direction). The second power supply line 16 may have a loop shape having one open side and may partially surround the display area DA.

A data signal of the data driver 20 may be transmitted to the pixel circuit PC through a data line DL electrically connected to an input line IL.

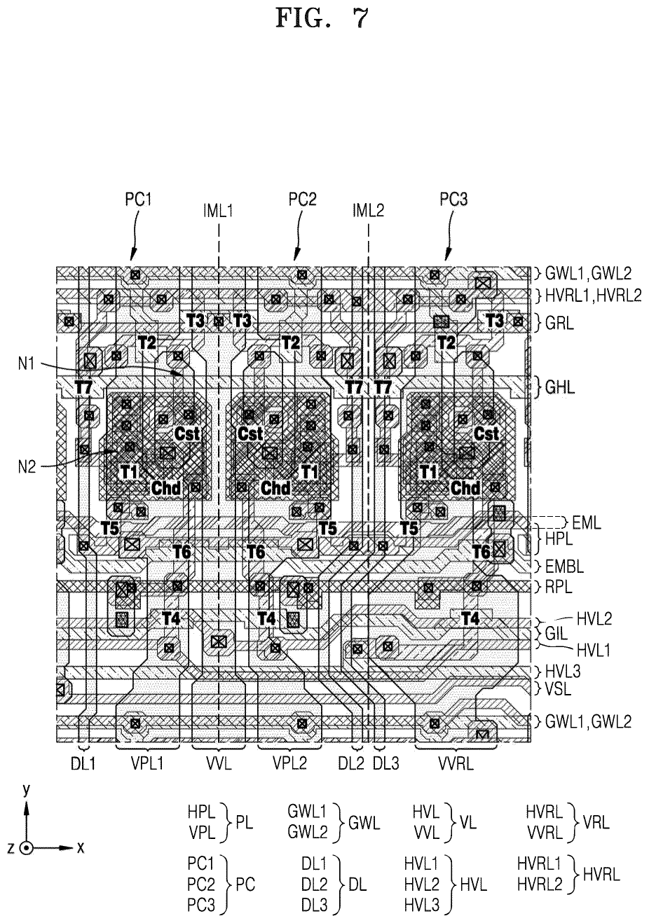

FIG. 7 is a schematic plan view of pixel circuits of the display panel 10 according to an embodiment. For convenience of explanation, FIG. 7 illustrates three pixel circuits disposed in the same row in a first direction (e.g., an x direction), for example, a first pixel circuit PC1, a second pixel circuit PC2, and a third pixel circuit PC3. However, the disclosure is not necessarily limited thereto. The display panel 10 may include the plurality of pixel circuits forming a row in the first direction (e.g., the x direction) and a column in a second direction (e.g., a y direction).

Referring to FIG. 7, each of the first to third pixel circuits PC1 to PC3 may include transistors and a capacitor. According to an embodiment, each of the first to third pixel circuits PC1 to PC3 may include first to seventh transistors T1 to T7, a storage capacitor Cst, and a hold capacitor Chd. Here, the first transistor T1 may include a driving transistor configured to output a driving current corresponding to a data signal, and the second to seventh transistors T2 to T7 may include switching transistors configured to transmit signals.

According to an embodiment, at least one of the first to seventh transistors T1 to T7 may include a p-channel metal-oxide semiconductor field-effect transistor (MOSFET) (a PMOS transistor) and the others may include n-channel MOSFETs (NMOS transistors). For example, the fifth transistor T5 may include a PMOS transistor, and the first, second, third, fourth, sixth, and seventh transistors T1, T2, T3, T4, T6, and T7 may include NMOS transistors. According to an embodiment, the fifth and sixth transistors T5 and T6 may include PMOS transistors, and the first, second, third, and fourth transistors T1, T2, T3, and T4 may include NMOS transistors. Alternatively, all of the first to seventh transistors T1 to T7 may include NMOS transistors or PMOS transistors. Hereinafter, the disclosure is mainly described according to an embodiment, in which the fifth transistor T5 may include a PMOS transistor including a silicon semiconductor, and the first, second, third, fourth, sixth, and seventh transistors T1, T2, T3, T4, T6, and T7 may include NMOS transistors including an oxide semiconductor.

At least one of the plurality of transistors T1 to T7 may include a transistor having a low-temperature polycrystalline silicon (LTPS) semiconductor layer, and at least one of the plurality of transistors T1 to T7 may include a transistor having an oxide semiconductor layer. For example, the fifth transistor T5 may include a semiconductor layer including polycrystalline silicon having a high reliability, and the first, second, third, fourth, sixth, and seventh transistors T1, T2, T3, T4, T6, and T7 may include an oxide semiconductor layer having a high carrier mobility and a low leakage current.

Each of the first to third pixel circuits PC1 to PC3 may be electrically connected to gate lines configured to transmit signals to a gate of each of the first to seventh transistors T1 to T7. For example, the pixel circuit PC may be connected to a scan line GWL configured to transmit a scan signal, an initialization gate line GBL configured to transmit an initialization signal, a reference gate line GRL configured to transmit a reference signal, a first emission control line EML configured to transmit a first emission control signal, a second emission control line EMBL configured to transmit a second emission control signal, a hold gate line GHL configured to transmit a hold signal, and a data line DL configured to transmit a data line. Also, each of the first to third pixel circuits PC1 to PC3 may be connected to a driving voltage line PL configured to transmit a driving voltage, a reference voltage line VRL configured to transmit a reference voltage, and an initialization voltage line VL configured to transmit an initialization voltage.

For example, the first transistor T1 may be electrically connected between the driving voltage line PL and the light-emitting diode LED (see FIG. 6). The first transistor T1 may include a gate electrode connected to a first node electrode N1 connected to the second transistor T2 and the third transistor T3. The first transistor T1 may include a first terminal connected to the driving voltage line PL and a second terminal connected to a second node electrode N2 connected to the sixth transistor T6. The first transistor T1 may have a dual-gate structure. The first transistor T1 may further include a lower gate electrode overlapping a channel area of the first transistor T1, in addition to a gate electrode connected to the first node electrode N1. The lower gate electrode may be connected to the second node electrode N2 and the hold capacitor Chd.

The first terminal of the first transistor T1 may be connected to the driving voltage line PL through the fifth transistor T5, and the second terminal of the first transistor T1 may be connected to a pixel electrode of the light-emitting diode LED (see FIG. 6). The first transistor T1 may receive a data signal according to a switching operation of the second transistor T2 and may control a current amount of a driving current flowing through the light-emitting diode LED (see FIG. 6).

The second transistor T2 may be electrically connected between the data line DL and the first node electrode N1. The second transistor T2 may include a gate connected to the scan line GWL, a first terminal connected to the data line DL, and a second terminal connected to the first node electrode N1. The second transistor T2 may be turned on in response to the scan signal transmitted through the scan line GWL and may electrically connect the data line DL with the first node electrode N1 and transmit the data signal transmitted through the data line DL to the first node electrode N1.

The third transistor T3 may be electrically connected between the first node electrode N1 and the reference voltage line VRL. The third transistor T3 may include a gate connected to the reference gate line GRL, a first terminal connected to the first node electrode N1, and a second terminal connected to the reference voltage line VRL. The third transistor T3 may be turned on in response to the reference signal transmitted through the reference gate line GRL and may transmit the reference voltage transmitted through the reference voltage line VRL to the first node electrode N1.

The fourth transistor T4 may be electrically connected between the first transistor T1 and the initialization voltage line VL. The fourth transistor T4 may include a gate connected to the initialization gate line GIL, a first terminal connected to the sixth transistor T6, and a second terminal connected to the initialization voltage line VL. The fourth transistor T4 may be turned on in response to the initialization signal transmitted through the initialization gate line GIL and may transmit the initialization voltage transmitted through the initialization voltage line VL to a pixel electrode of the light-emitting diode LED (see FIG. 6).

The fifth transistor T5 may be electrically connected between the driving voltage line PL and the first transistor T1. The fifth transistor T5 may include a gate connected to the first emission control line EML, a first terminal connected to the driving voltage line PL, and a second terminal connected to the first transistor T1. The fifth transistor T5 may be turned on or turned off in response to the first emission control signal transmitted through the first emission control line EML.

The sixth transistor T6 may be connected between the first transistor T1 and the light-emitting diode LED (see FIG. 6). The sixth transistor T6 may include a gate connected to the second emission control line EMBL, a first terminal connected to the second node electrode N2, and a second terminal connected to the light-emitting diode LED (see FIG. 6). The sixth transistor T6 may be turned on in response to the second emission control signal transmitted through the second emission control line EMBL and may connect the second node electrode N2 with the pixel electrode of the light-emitting diode LED (see FIG. 6).

FIG. 7 illustrates that the fifth transistor T5 and the sixth transistor T6 may operate in response to the different emission control signals from each other. However, the disclosure is not necessarily limited thereto. According to an embodiment, the fifth transistor T5 and the sixth transistor T6 may operate in response to the same emission control signal.

The seventh transistor T7 may be electrically connected between the hold capacitor Chd and the reference voltage line VRL. The seventh transistor T7 may include a gate connected to the hold gate line GHL, a first terminal connected to the hold capacitor Chd, and a second terminal connected to the reference voltage line VRL. The seventh transistor T7 may be turned on or turned off in response to the hold signal transmitted through the hold gate line GHL and may adjust the hold capacitor Chd.

The storage capacitor Cst may be connected between the first node electrode N1 and the second node electrode N2. For example, the pixel circuit PC, according to an embodiment, may include a source follower type-circuit, in which the storage capacitor Cst is connected between the first node electrode N1 and the second node electrode N2. The storage capacitor Cst may include a first storage electrode and a second storage electrode that opposite to each other. The first storage electrode may be connected to the first node electrode N1 and the second storage electrode may be connected to the second node electrode N2. The storage capacitor Cst may store a threshold voltage of the first transistor T1 and a voltage corresponding to the data signal.

The hold capacitor Chd may be connected between the seventh transistor T7 and the second node electrode N2. The hold capacitor Chd may include a first hold electrode and a second hold electrode that are opposite to each other. The first hold electrode may be connected to the seventh transistor T7 and the second hold electrode may be connected to the second node electrode N2. The hold capacitor Chd may allow the lower gate electrode of the first transistor T1 and the second node electrode N2 to have constant voltages which are not changed even when a peripheral signal is changed.

Referring to FIG. 7, the transistors and the capacitors of the first pixel circuit PC1 may be symmetrically disposed with the transistors and the capacitors of the second pixel circuit PC2, respectively. For example, the first transistor T1 of the first pixel circuit PC1 may be symmetrical with the first transistor T1 of the second pixel circuit PC2 with respect to a virtual line IML1 crossing between the first pixel circuit PC1 and the second pixel circuit PC2 in the second direction (e.g., the y direction). Similarly, the second to sixth transistors T2 to T5, the storage capacitor Cst, and the hold capacitor Chd of the first pixel circuit PC1 may be respectively symmetrical with the second to sixth transistors T2 to T6, the storage capacitor Cst, and the hold capacitor Chd of the second pixel circuit PC2 with respect to the virtual line IML1.

Likewise, the transistors and the capacitors of the second pixel circuit PC2 may be symmetrically disposed with the transistors and the capacitors of the third pixel circuit PC3, respectively. For example, the first transistor T1 of the second pixel circuit PC2 may be symmetrical with the first transistor T1 of the third pixel circuit PC3 with respect to a virtual line IML2 crossing between the second pixel circuit PC2 and the third pixel circuit PC3 in the second direction (e.g., the y direction). Similarly, the second to sixth transistors T2 to T6, the storage capacitor Cst, and the hold capacitor Chd of the second pixel circuit PC2 may be respectively symmetrical with the second to sixth transistors T2 to T6, the storage capacitor Cst, and the hold capacitor Chd of the third pixel circuit PC3 with respect to the virtual line IML2.

The gate lines electrically connected to the first to third pixel circuits PC1 to PC3, for example, the scan line GWL, the initialization gate line GIL, the reference gate line GRL, the first emission control line EML, the second emission control line EMBL, and the hold gate line GHL may extend in the first direction (e.g., the x direction).

Each of the first to third pixel circuits PC1 to PC3 may be electrically connected to the data line DL crossing each of the first to third pixel circuit circuits PC1 to PC3. For example, the first pixel circuit PC1 may be electrically connected to a first data line DL1 crossing the first pixel circuit PC1, the second pixel circuit PC2 may be electrically connected to a second data line DL2 crossing the second pixel circuit PC2, and the third pixel circuit PC3 may be connected to a third data line DL3 crossing the third pixel circuit PC3. The data line DL may extend in the second direction (e.g., the y direction). With respect to the first direction (e.g., the x direction), the first data line DL1 may be disposed at a left side of the first transistor T1 in the first pixel circuit PC1, the second data line DL2 may be disposed at a right side of the first transistor T1 in the second pixel circuit PC2, and the third data line DL3 may be disposed at a left side of the first transistor T1 in the third pixel circuit PC3. For example, the first data line DL1 and the second data line DL2 may be disposed to be far from each other with respect to the virtual line IML1, and the second data line DL2 and the third data line DL3 may be disposed adjacent to each other with respect to the virtual line IML2.

Each of the first to third pixel circuits PC1 to PC3 may be electrically connected to the voltage line crossing each of the first to third pixel circuit circuits PC1 to PC3. For example, each of the first to third pixel circuits PC1 to PC3 may be electrically connected to the reference voltage line VRL, the initialization voltage line VL, the driving voltage line PL, and the common voltage line VSL. The reference voltage line VRL may include a horizontal reference voltage line HVRL extending in the first direction (e.g., the x direction) and a vertical reference voltage line VVRL extending in the second direction (e.g., the y direction). The horizontal reference voltage line HVRL and the vertical reference voltage line VVRL may be electrically connected to each other in a crossing area thereof. According to an embodiment, the vertical reference voltage line VVRL may be disposed in an area in which the third pixel circuit PC3 is disposed.

The initialization voltage line VL may include a horizontal initialization voltage line HVL extending in the first direction (e.g., the x direction) and a vertical initialization voltage line VVL extending in the second direction (e.g., the y direction). The horizontal initialization voltage line HVL and the vertical initialization voltage line VVL may be electrically connected to each other in a crossing area thereof. According to an embodiment, the vertical initialization voltage line VVL may be disposed at an edge between the first pixel circuit PC1 and the second pixel circuit PC2. For example, the vertical initialization voltage line VVL may be disposed on the virtual line IML1 described above, wherein a portion of the vertical initialization voltage line VVL may be disposed in an area in which the first pixel circuit PC1 is disposed, and the other portion of the vertical initialization voltage line VVL may be disposed in an area in which the second pixel circuit PC2 is disposed. The horizontal initialization voltage line HVL may include a plurality of lines. For example, the horizontal initialization voltage line HVL may include a first horizontal initialization voltage line HVL1 configured to transmit an initialization voltage to the first pixel circuit PC1, a second horizontal initialization voltage line HVL2 configured to transmit an initialization voltage to the second pixel circuit PC2, and a third horizontal initialization voltage line HVL3 configured to transmit an initialization voltage to the third pixel circuit PC3.

The driving voltage line PL may include a horizontal driving voltage line HPL extending in the first direction (e.g., the x direction) and a vertical driving voltage line VPL extending in the second direction (e.g., the y direction). According to an embodiment, the vertical driving voltage line VPL may be disposed in each of the area in which the first pixel circuit PC1 is disposed and the area in which the second pixel circuit PC2 is disposed. The driving voltage line PL disposed at the first pixel circuit PC1 and the driving voltage line PL disposed at the second pixel circuit PC2 may be symmetrical with each other with respect to the virtual line IML1 described above.

The common voltage line VSL may extend in the first direction (e.g., the x direction) and may cross the first to third pixel circuits PC1 to PC3. The common voltage line VSL may be disposed in the display area DA (see FIG. 6) and may be electrically connected to the second power supply line 16 (see FIG. 6) disposed in the peripheral area PA and configured to transmit a common voltage.

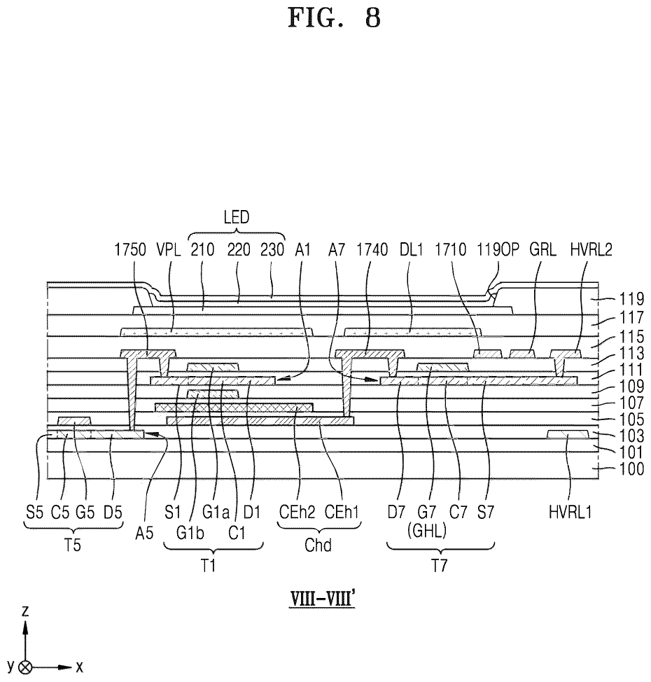

FIG. 8 is a cross-sectional view of the display panel 10, according to an embodiment, taken along a line VIII-VIII′ of FIG. 6.

Referring to FIG. 8, the display panel 10 may include a circuit layer including the transistors and the capacitors disposed on the substrate 100, and a display element layer disposed on the circuit layer described above and including the light-emitting diode LED. The circuit layer may include the transistors and the capacitors described above with reference to FIG. 7. Also, FIG. 8 illustrates the first transistor T1, the fifth transistor T5, the seventh transistor T7, and the hold capacitor Chd.

The substrate 100 may include a glass material, a ceramic material, a metal material, a plastic material, or a flexible or bendable material. When the substrate 100 is flexible or bendable, the substrate 100 may include polymer resins, such as polyether sulphone (PES), polyacrylate, polyether imide (PEI), polyethylene naphthalate (PEN), polyethylene terephthalate (PET), polyphenylene sulfide (PPS), polyarylate, polyimide (PI), polycarbonate, cellulose acetate propionate (CAP), etc.

The substrate 100 may have a single-layered or multi-layered structure including the materials described above, and when the substrate 100 has a multi-layered structure, the substrate 100 may further include an inorganic layer. For example, the substrate 100 may have a structure in which a layer including the polymer resins described above and a barrier layer including an inorganic insulating material are alternately stacked.

A buffer layer 101 may be disposed on the substrate 100. The buffer layer 101 may include an inorganic insulating layer including an inorganic insulating material such as silicon nitride and/or silicon oxide and may have a single-layered or multi-layered structure including the materials described above.

A transistor including a silicon semiconductor layer may be disposed on the buffer layer 101. With respect to this aspect, FIG. 8 illustrates a fifth semiconductor layer A5 of the fifth transistor T5. The fifth semiconductor layer A5 may include polysilicon. The fifth semiconductor layer A5 may include a channel area C5 and impurity areas S5 and D5 disposed at both sides of the channel area C5 and doped with impurities. One of the impurity areas S5 and D5 of the fifth semiconductor layer A5 may be a source, and the other may be a drain.

According to some embodiments, a lower metal layer may further be provided between the buffer layer 101 and the silicon semiconductor layer. The lower metal layer may include one or more materials selected from among Al, Pt, Pd, Ag, Mg, Au, Ni, Nd, Ir, Cr, Li, Ca, Mo, Ti, W, and Cu. The lower metal layer may have a voltage level of a constant voltage. For example, the lower metal layer may be electrically connected to the first power supply line 15 (see FIG. 6) at the outside of the display area DA (see FIG. 6).

A first gate insulating layer 103 may be disposed on the fifth semiconductor layer A5. The first gate insulating layer 103 may include an inorganic insulating layer including an inorganic insulating material such as silicon oxide, silicon nitride, and/or silicon oxynitride and may have a single-layered or multi-layered structure including the materials described above.

A fifth gate electrode G5 may be disposed on the first gate insulating layer 103 and may overlap the channel area C5 of the fifth semiconductor layer A5. A first hold electrode CEh1 of the hold capacitor Chd may be disposed on the same layer as the fifth gate electrode G5, for example, on the first gate insulating layer 103.

The fifth gate electrode G5 and the first hold electrode CEh1 of the hold capacitor Chd may include the same material as each other. Each of the fifth gate electrode G5 and the first hold electrode CEh1 of the hold capacitor Chd may include Al, Pt, Pd, Ag, Mg, Au, Ni, Nd, Ir, Cr, Li, Ca, Mo, Ti, W, and/or Cu and may include a single layer or multi-layers including the materials described above. According to an embodiment, each of the fifth gate electrode G5 and the first hold electrode CEh1 of the hold capacitor Chd may include a single layer including Mo.

A second gate insulating layer 105 may be disposed on the fifth gate electrode G5 and the first hold electrode CEh1 of the hold capacitor Chd. The second gate insulating layer 105 may include an inorganic insulating layer including an inorganic insulating material such as silicon oxide, silicon nitride, and/or silicon oxynitride and may have a single-layered or multi-layered structure including the materials described above. According to an embodiment, the second gate insulating layer 105 may include a different material from the first gate insulating layer 103. For example, the first gate insulating layer 103 may include silicon oxide and the second gate insulating layer 105 may include silicon nitride.

A second hold electrode CEh2 of the hold capacitor Chd may be disposed on the second gate insulating layer 105. The second hold electrode CEh2 may overlap the first hold electrode CEh1 of the hold capacitor Chd. The second hold electrode CEh2 of the hold capacitor Chd may include Al, Pt, Pd, Ag, Mg, Au, Ni, Nd, Ir, Cr, Li, Ca, Mo, Ti, W, and/or Cu and may include a single layer or multi-layers including the materials described above. According to an embodiment, the second hold electrode CEh2 may include a single layer including Mo.

A third gate insulating layer 107 may be disposed on the second hold electrode CEh2. The third gate insulating layer 107 may include an inorganic insulating layer including an inorganic insulating material such as silicon oxide, silicon nitride, and/or silicon oxynitride and may have a single-layered or multi-layered structure including the materials described above.

A first lower gate electrode G1b of the first transistor T1 may be disposed on the third gate insulating layer 107. As described above, the first transistor T1 may have a dual gate structure and may include a first gate electrode G1a overlapping a channel area of the first transistor T1 and the first lower gate electrode G1b. The first lower gate electrode G1b may include Al, Pt, Pd, Ag, Mg, Au, Ni, Nd, Ir, Cr, Li, Ca, Mo, Ti, W, and/or Cu and may include a single layer or multi-layers including the materials described above.

A first interlayer insulating layer 109 may be disposed on the first lower gate electrode G1b. The first interlayer insulating layer 109 may include an inorganic insulating layer including an inorganic insulating material such as silicon oxide, silicon nitride, and/or silicon oxynitride and may have a single-layered or multi-layered structure including the materials described above. For example, the first interlayer insulating layer 109 may have a stack structure including a layer including silicon oxide and a layer including silicon nitride.

A first semiconductor layer A1 of the first transistor T1 and a seventh semiconductor layer A7 of the seventh transistor T7 may be disposed on the first interlayer insulating layer 109 and may include the same material as each other. The first semiconductor layer A1 of the first transistor T1 and the seventh semiconductor layer A7 of the seventh transistor T7 may include an oxide semiconductor, and the oxide semiconductor may include at least one element of In, Ga, Sn, Zr, V, Hf, Cd, Ge, Cr, Ti, Al, Cs, Ce, and Zn. For example, the oxide semiconductor may include InSnZnO (ITZO) or InGaZnO (IGZO).

The first semiconductor layer A1 may include a channel area C1 and conductive areas S1 and D1 disposed at both sides of the channel area C1. Any one of the conductive areas S1 and D1 may be a source, and the other may be a drain. Likewise, the seventh semiconductor layer A7 may include a channel area C7 and conductive areas S7 and D7 disposed at both sides of the channel area C7. Any one of the conductive areas S7 and D7 may be a source, and the other may be a drain.

The first semiconductor layer A1 and the seventh semiconductor layer A7 may be disposed on a different layer from the fifth semiconductor layer A5 described above. A vertical distance from the substrate 100 to the first semiconductor layer A1 may be greater than a vertical distance from the substrate 100 to the fifth semiconductor layer A5.

A fourth gate insulating layer 111 may be disposed on the first semiconductor layer A1 and the seventh semiconductor layer A7. The fourth gate insulating layer 111 may include an inorganic insulating layer including an inorganic insulating material such as silicon oxide, silicon nitride, and/or silicon oxynitride and may have a single-layered or multi-layered structure including the materials described above. According to an embodiment, the fourth gate insulating layer 111 may include a single layer including silicon oxide.

FIG. 8 illustrates that the fourth gate insulating layer 111 may be in contact with an upper surface of the first interlayer insulating layer 109 along a side surface of the first semiconductor layer A1. However, the disclosure is not necessarily limited thereto. According to an embodiment, the fourth gate insulating layer 111 may be formed to have substantially the same pattern and/or the same width as the first gate electrode G1a and a seventh gate electrode G7 described below. Alternatively, according to an embodiment, the fourth gate insulating layer 111 may be formed to have a greater pattern and/or a greater width than the first gate electrode G1a described below and may be formed to have a less pattern and/or a less width than the first semiconductor layer A1. Likewise, the fourth gate insulating layer 111 may be formed to have a greater pattern and/or a greater width than the seventh gate electrode G7 described below and may be formed to have a less pattern and/or a less width than the seventh semiconductor layer A7. For example, the fourth gate insulating layer 111 might not be in contact with the upper surface of the first interlayer insulating layer 109 along the side surface of the first semiconductor layer A1.

The first gate electrode G1a and the seventh gate electrode G7 may be disposed on the fourth gate insulating layer 111. The first gate electrode G1a may overlap the channel area C1 of the first semiconductor layer Al, and the seventh gate electrode G7 may overlap the channel area C7 of the seventh semiconductor layer A7. Although it is to be described below, the seventh gate electrode G7 may be a portion of the hold gate line GHL. The first gate electrode G1a and the seventh gate electrode G7 may include Al, Pt, Pd, Ag, Mg, Au, Ni, Nd, Ir, Cr, Li, Ca, Mo, Ti, W, and/or Cu and may include a single layer or multi-layers including the materials described above. According to an embodiment, the first gate electrode G1a and the seventh gate electrode G7 may have a tri-layered structure of a titanium layer/an aluminum layer/a titanium layer.

A second interlayer insulating layer 113 may be disposed on the first gate electrode G1a and the seventh gate electrode G7. The second interlayer insulating layer 113 may include an inorganic insulating layer including an inorganic insulating material such as silicon oxide, silicon nitride, and/or silicon oxynitride and may have a single-layered or multi-layered structure including the materials described above. According to an embodiment, the second interlayer insulating layer 113 may have a stack structure including a layer including silicon nitride and a layer including silicon oxynitride.

An eighth conductive pattern 1710, an eleventh conductive pattern 1740, a twelfth conductive pattern 1750, a reference gate line GRL, and a second horizontal reference voltage line HVRL2 may be disposed on the same layer as one another, for example, on the second interlayer insulating layer 113. The twelfth conductive pattern 1750 may be a connection electrode connecting the fifth semiconductor layer A5 to the first semiconductor layer Al, and the eleventh conductive pattern 1740 may be a connection electrode connecting the first hold electrode CEh1 to the seventh semiconductor layer A7. The eighth conductive pattern 1710, the eleventh conductive pattern 1740, the twelfth conductive pattern 1750, the reference gate line GRL, and the second horizontal reference voltage line HVRL2 may include the same material as one another. The eighth conductive pattern 1710, the eleventh conductive pattern 1740, the twelfth conductive pattern 1750, the reference gate line GRL, and the second horizontal reference voltage line HVRL2 may include Al, Pt, Pd, Ag, Mg, Au, Ni, Nd, Ir, Cr, Li, Ca, Mo, Ti, W, and/or Cu and may include a single layer or multi-layers including the materials described above. According to an embodiment, the eighth conductive pattern 1710, the eleventh conductive pattern 1740, the twelfth conductive pattern 1750, the reference gate line GRL, and the second horizontal reference voltage line HVRL2 may have a tri-layered structure of a titanium layer/an aluminum layer/a titanium layer.

A first organic insulating layer 115 may be disposed on the eighth conductive pattern 1710, the eleventh conductive pattern 1740, the twelfth conductive pattern 1750, the reference gate line GRL, and the second horizontal reference voltage line HVRL2. The first organic insulating layer 115 may include an organic insulating material, such as acryl, benzocyclobutene (BCB), polyimide, or hexamethyldisiloxane (HMDSO).

A first data line DL1 and a vertical driving voltage line VPL may be disposed on the first organic insulating layer 115. The first data line DL1 and the vertical driving voltage line VPL may include Al, Pt, Pd, Ag, Mg, Au, Ni, Nd, Ir, Cr, Li, Ca, Mo, Ti, W, and/or Cu and may include a single layer or multi-layers including the materials described above. According to an embodiment, the first data line DL and the vertical driving voltage line VPL may have a tri-layered structure of a titanium layer/an aluminum layer/a titanium layer.

A second organic insulating layer 117 may be disposed on the data line DL and the vertical driving voltage line VPL. The second organic insulating layer 117 may include an organic insulating material, such as acryl, BCB, polyimide, or HMDSO.

The light-emitting diode LED may be disposed on the second organic insulating layer 117. The light-emitting diode LED may include a pixel electrode 210, an intermediate layer 220, and an opposite electrode 230 which are disposed on the second organic insulating layer 117.

An outer portion of the pixel electrode 210 may be covered by a bank layer 119, and an inner portion of the pixel electrode 210 may overlap the intermediate layer 220 through an opening 119OP of the bank layer 119. The pixel electrode 210 may correspond to each light-emitting diode LED, and the opposite electrode 230 may correspond to the plurality of light-emitting diodes LED. For example, the opposite electrode 230 may extend to overlap the plurality of pixel electrodes 210. The plurality of light-emitting diodes LED may share the opposite electrode 230, and a stack structure of the pixel electrode 210, the intermediate layer 220, and the opposite electrode 230 may correspond to the light-emitting diode LED.

The intermediate layer 220 may include an emission layer. According to some embodiments, the intermediate layer 220 may further include an emission layer and a functional layer. The functional layer may include a hole transport layer (HTL), a hole injection layer (HIL), an electron transport layer (ETL), and/or an electron injection layer (EIL). According to some embodiments, the intermediate layer 220 may include a first stack including an emission layer and a functional layer, a second stack including an emission layer and a functional layer, and a charge generation layer between the first stack and the second stack. The charge generation layer may include a negative charge generation layer and a positive charge generation layer. Based on the negative charge generation layer and the positive charge generation layer, the emission efficiency of the tandem-type light-emitting diode LED including the plurality of emission layers may further be increased.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The opposite electrode 230 may include a conductive material having a low work function. The opposite electrode 230 may include a (semi-) transparent layer including Ag, Mg, Al, Pt, Pd, Au, Ni, Nd, Ir, Cr, Li, Ca, or an alloy thereof. Alternatively, the opposite electrode 230 may further include a layer, such as ITO, IZO, ZnO, or In₂O₃, on the (semi-) transparent layer including the material described above.

An encapsulation layer may be disposed on the light-emitting diode LED. The encapsulation layer may include a first inorganic encapsulation layer, a second inorganic encapsulation layer, and an organic encapsulation layer therebetween.

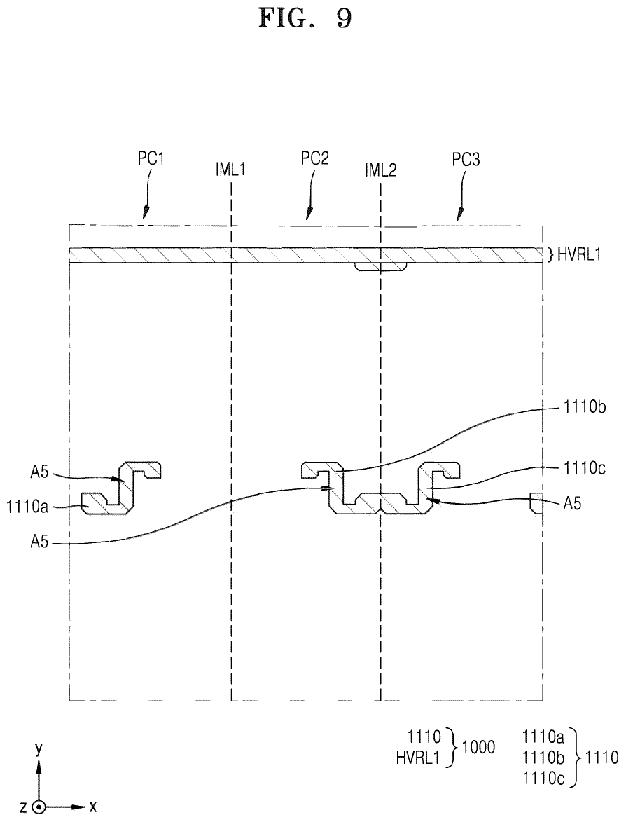

FIGS. 9 to 16 are plan views for showing a process of forming a pixel circuit of a display panel according to an embodiment. FIGS. 9 to 16 show the process of forming elements corresponding to the first pixel circuit PC1, the second pixel circuit PC2, and the third pixel circuit PC3 described with reference to FIG. 7. For convenience of explanation, it is described that the first pixel circuit PC1 may be located at an (i)th row and a (j)th column, the second pixel circuit PC2 may be located at the (i)th row and a (j+1)th column, and the third pixel circuit PC3 may be located at the (i)th row and a (j+2)th column. Here, i and j are positive integers.

Referring to FIG. 9, a silicon semiconductor layer 1100 may be disposed on a substrate. For example, the silicon semiconductor layer 1100 may include amorphous silicon or polysilicon. For example, the silicon semiconductor layer 1100 may include LTPS. The silicon semiconductor layer 1100 may include a first silicon semiconductor pattern 1110 and a first horizontal reference voltage line HVRL1 as illustrated in FIG. 9.

The first silicon semiconductor pattern 1100 may include a first-1 silicon semiconductor pattern 1110a disposed in the first pixel circuit PC1, a first-2 silicon semiconductor pattern 1110b disposed in the second pixel circuit PC2, and a first-3 silicon semiconductor pattern 1110c disposed in the third pixel circuit PC3. The first-1 silicon semiconductor pattern 1110a may have an isolated shape and may include a curved portion. The first-1 silicon semiconductor pattern 1110a may include the fifth semiconductor layer A5 of the first pixel circuit PC1. The first-2 silicon semiconductor pattern 1110b and the first-3 silicon semiconductor pattern 1110c may be connected to each other and integrally formed. The first-2 silicon semiconductor pattern 1110b and the first-3 silicon semiconductor pattern 1110c may be symmetrical with each other with respect to a virtual line IML2. The first-2 silicon semiconductor pattern 1110b may include the fifth semiconductor layer A5 of the second pixel circuit PC2, and the first-3 silicon semiconductor pattern 1110c may include the fifth semiconductor layer A5 of the third pixel circuit PC3. For example, the fifth semiconductor layer A5 of the second pixel circuit PC2 and the fifth semiconductor layer A5 of the third pixel circuit PC3 may be integrally connected to each other.

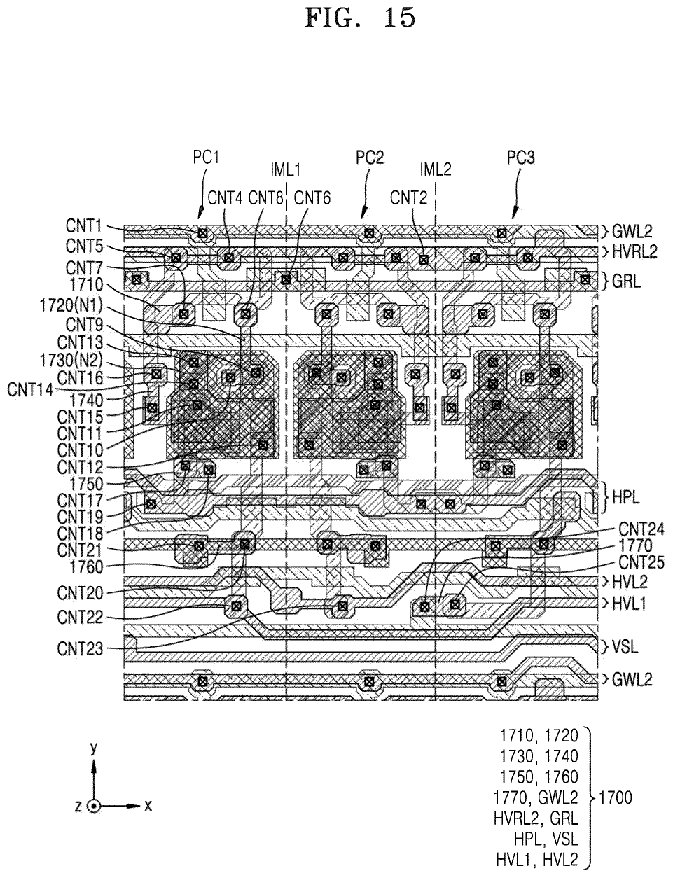

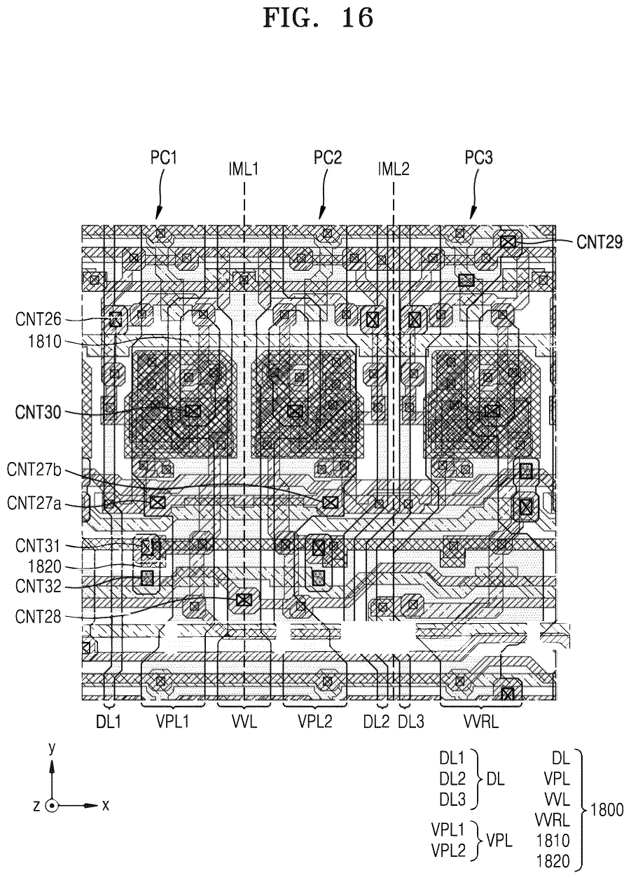

The first horizontal reference voltage line HVRL1 may extend in a first direction (e.g., an x direction) and may cross the first pixel circuit PC1, the second pixel circuit PC2, and the third pixel circuit PC3. The first horizontal reference voltage line HVRL1 may cross pixel circuits disposed in the same row as the first pixel circuit PC1, the second pixel circuit PC2, and the third pixel circuit PC3. The first horizontal reference voltage line HVRL1 may be electrically connected to a second horizontal reference voltage line HVRL2 (see FIG. 15) and a vertical reference voltage line VVRL (see FIG. 16) and may transmit a reference voltage to each pixel circuit. The first horizontal reference voltage line HVRL1 may overlap the second horizontal reference voltage line HVRL2 (see FIG. 15) in a plan view.

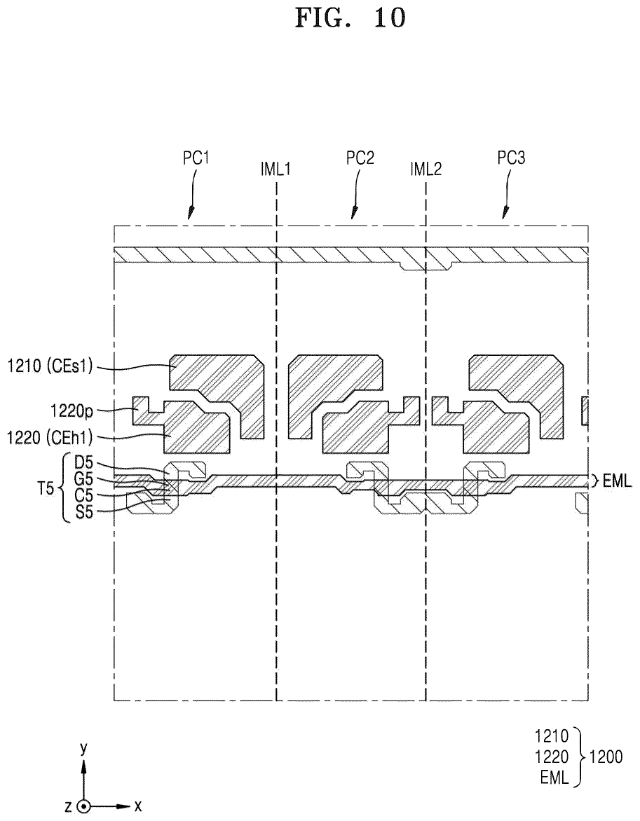

Referring to FIG. 10, a first conductive layer 1200 may be disposed on the silicon semiconductor layer 1100. The first conductive layer 1200 may include Al, Pt, Pd, Ag, Mg, Au, Ni, Nd, Ir, Cr, Li, Ca, Mo, Ti, W, and/or Cu and may include a single layer or multi-layers including the materials described above.

The first conductive layer 1200 may include a first emission control line EML, a first conductive pattern 1210, and a second conductive pattern 1220. The first emission control line EML, the first conductive pattern 1210, and the second conductive pattern 1220 may be spaced apart from each other.

The first emission control line EML may extend in the first direction (e.g., the x direction) and may cross the first pixel circuit PC1, the second pixel circuit PC2, and the third pixel circuit PC3. The first emission control line EML may cross the pixel circuits disposed in the same row as the first pixel circuit PC1, the second pixel circuit PC2, and the third pixel circuit PC3.

The first emission control line EML may include the fifth gate electrode G5 of the fifth transistor T5 of each of the first to third pixel circuits PC1 to PC3. A portion of the first emission control line EML, the portion overlapping the first silicon semiconductor pattern 1110, may correspond to the fifth gate electrode G5 of the fifth transistor T5. The fifth semiconductor layer A5 (see FIG. 9) of the fifth transistor T5 may include a channel area C5 overlapping the fifth gate electrode G5 and doping areas S5 and D5 disposed at both sides of the channel area C5, respectively, and doped with impurities. One of the doping areas S5 and D5 may be a source area, and the other may be a drain area. The source area and the drain area may correspond to a source electrode and a drain electrode, respectively. The positions of the source area and the drain area may be exchanged according to the characteristic of a transistor.

The first conductive pattern 1210 and the second conductive pattern 1220 may be disposed in each of the first to third pixel circuits PC1 to PC3. Each of the first conductive pattern 1210 and the second conductive pattern 1220 may have an isolated shape. The first conductive pattern 1210 and the second conductive pattern 1220 of the first pixel circuit PC1 may be symmetrically disposed with the first conductive pattern 1210 and the second conductive pattern 1220 of the second pixel circuit PC2 with respect to a virtual line IML1. Likewise, the first conductive pattern 1210 and the second conductive pattern 1220 of the second pixel circuit PC2 may be symmetrically disposed with the first conductive pattern 1210 and the second conductive pattern 1220 of the third pixel circuit PC3 with respect to the virtual line IML2.

The first conductive pattern 1210 may include a first storage electrode CEs1 of the storage capacitor Cst described with reference to FIG. 7. The second conductive pattern 1220 may include the first hold electrode CEh1 of the hold capacitor Chd described with reference to FIG. 7. Here, the second conductive pattern 1220 may further include a protrusion portion 1220p to be connected to the seventh transistor T7 (see FIG. 7). The seventh transistor T7 (see FIG. 7) may be electrically connected to the first hold electrode CEh1 through the protrusion portion 1220p of the second conductive pattern 1220.

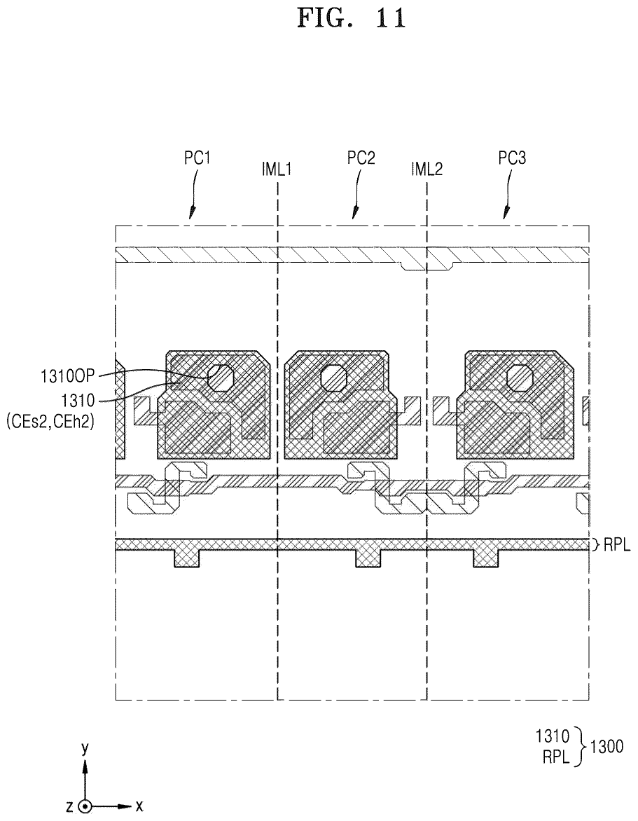

Referring to FIG. 11, a second conductive layer 1300 may be disposed on the first conductive layer 1200. The second conductive layer 1300 may include Al, Pt, Pd, Ag, Mg, Au, Ni, Nd, Ir, Cr, Li, Ca, Mo, Ti, W, and/or Cu and may include a single layer or multi-layers including the materials described above.

The second conductive layer 1300 may include a repair line RPL and a third conductive pattern 1310. The repair line RPL and the third conductive pattern 1310 may be spaced apart from each other.

The repair line RPL may extend in the first direction (e.g., the x direction) and may cross the first pixel circuit PC1, the second pixel circuit PC2, and the third pixel circuit PC3. The repair line RPL may cross the pixel circuits disposed in the same row as the first pixel circuit PC1, the second pixel circuit PC2, and the third pixel circuit PC3. When the pixel circuit PC (see FIG. 7) is defective, the light-emitting diodes LED may be separated from the defective pixel circuit and the light-emitting diode LED may be connected to a dummy pixel circuit through the repair line RPL. The dummy pixel circuit may generate a driving current corresponding to a data signal and supply the driving current to the light-emitting diode LED through the repair line RPL, so that the light-emitting diode LED may normally operate. Thus, the repair line RPL may overlap a thirteenth conductive pattern 1760 (see FIG. 15) and a sixteenth conductive pattern 1820 (see FIG. 16) which are connected to the light-emitting diode LED. The light-emitting diode LED may be insulated from the repair line RPL, but may be electrically connected to the repair line RPL in a subsequent repair process.

The third conductive pattern 1310 disposed in each of the first to third pixel circuits PC1 to PC3 may have an isolated shape. The third conductive pattern 1310 disposed in the first pixel circuit PC1 and the third conductive pattern 1310 disposed in the second pixel circuit PC2 may be apart from each other and may be substantially symmetrically disposed with each other with respect to the virtual line IML1 described above. The third conductive pattern 1310 disposed in the second pixel circuit PC2 and the third conductive pattern 1310 disposed in the third pixel circuit PC3 may be apart from each other and may be substantially symmetrically disposed with each other with respect to the virtual line IML2 described above.

The third conductive pattern 1310 may overlap each of the first conductive pattern 1210 (see FIG. 10) and the second conductive pattern 1220 (see FIG. 10) of the first conductive layer 1200 (see FIG. 10). The third conductive pattern 1310 may include a second storage electrode CEs2 of the storage capacitor Cst (see FIG. 7) and the second hold electrode CEh2 of the hold capacitor Chd (see FIG. 7). A portion of the third conductive pattern 1310, the portion overlapping the first conductive pattern 1210 (see FIG. 10) which is the first storage electrode CEs1 (see FIG. 10), may be the second storage electrode CEs2 of the storage capacitor Cst (see FIG. 7). A portion of the third conductive pattern 1310, the portion overlapping the second conductive pattern 1220 (see FIG. 10) which is the first hold electrode CEh1 (see FIG. 10), may be the second hold electrode CEh2 of the hold capacitor Chd (see FIG. 7). For example, the second storage electrode CEs2 of the storage capacitor Cst (see FIG. 7) and the second hold electrode CEh2 of the hold capacitor Chd (see FIG. 7) may be integrally formed with each other. The third conductive pattern 1310 may include an opening 1310OP having a closed shape in an area in which the third conductive pattern 1310 overlaps the first conductive pattern 1210 (see FIG. 10).

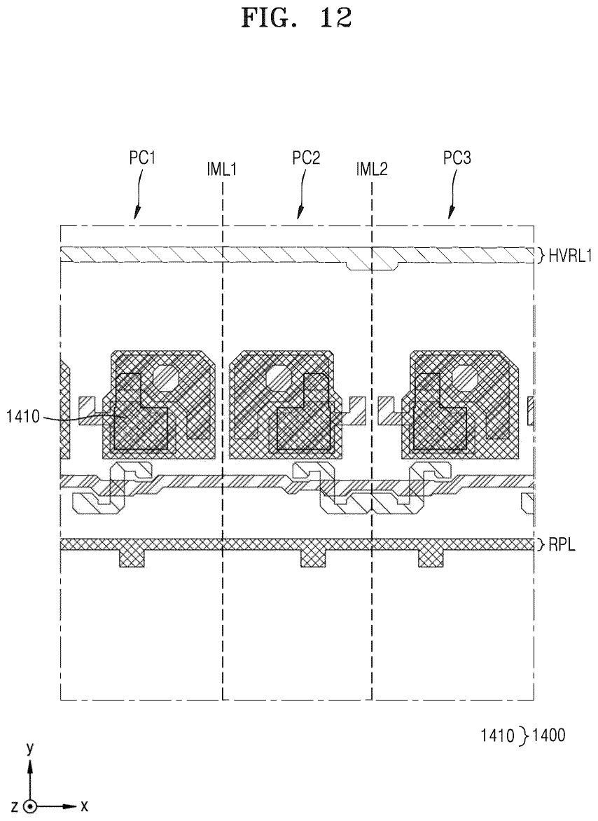

Referring to FIG. 12, a third conductive layer 1400 may be disposed on the second conductive layer 1300. The third conductive layer 1400 may include Al, Pt, Pd, Ag, Mg, Au, Ni, Nd, Ir, Cr, Li, Ca, Mo, Ti, W, and/or Cu and may include a single layer or multi-layers including the materials described above.

The third conductive layer 1400 may include a fourth conductive pattern 1410.

The fourth conductive pattern 1410 disposed in each of the first to third pixel circuits PC1 to PC3 may have an isolated shape. The fourth conductive pattern 1410 disposed in the first pixel circuit PC1 may be apart from the fourth conductive pattern 1410 disposed in the second pixel circuit PC2 and may be substantially symmetrically disposed with the fourth conductive pattern 1410 disposed in the second pixel circuit PC2 with respect to the virtual line IML1 described above. The fourth conductive pattern 1410 disposed in the second pixel circuit PC2 may be apart from the fourth conductive pattern 1410 disposed in the third pixel circuit PC3 and may be substantially symmetrically disposed with the fourth conductive pattern 1410 disposed in the third pixel circuit PC3 with respect to the virtual line IML2 described above.

According to an embodiment, the fourth conductive pattern 1410 may overlap the third conductive pattern 1310 (see FIG. 11). The fourth conductive pattern 1410 may include the first lower gate electrode G1b (see FIG. 8) of the first transistor T1 (see FIG. 7) and may be electrically connected to a tenth conductive pattern 1730 (see FIG. 15) described below.

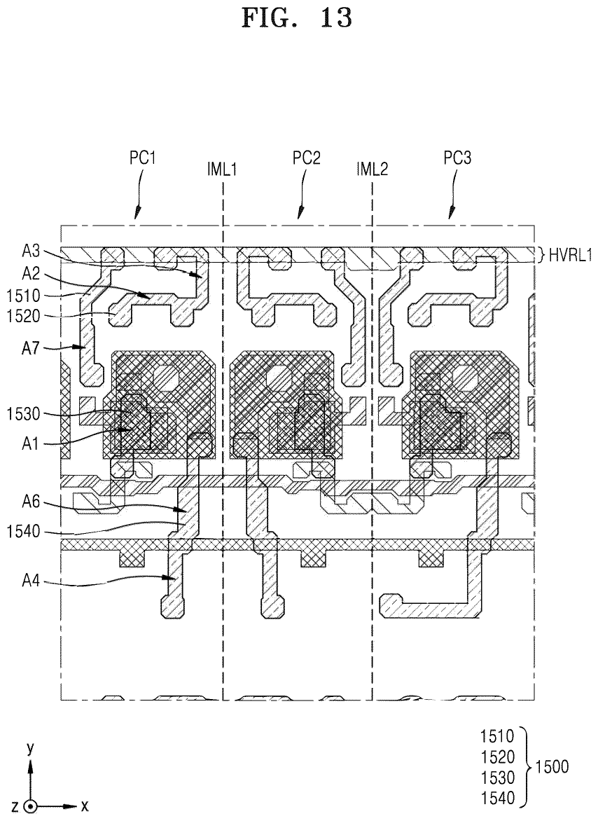

Referring to FIG. 13, an oxide semiconductor layer 1500 may be disposed on the third conductive layer 1400. For example, the oxide semiconductor layer 1500 may include an oxide semiconductor, and the oxide semiconductor may include at least one element of In, Ga, Sn, Zr, V, Hf, Cd, Ge, Cr, Ti, Al, Cs, Ce, and Zn. For example, the oxide semiconductor layer 1500 may include ITZO or IGZO.

The oxide semiconductor layer 1500 may include a first oxide semiconductor pattern 1510, a second oxide semiconductor pattern 1520, a third oxide semiconductor pattern 1530, and a fourth oxide semiconductor pattern 1540. The first oxide semiconductor pattern 1510, the second oxide semiconductor pattern 1520, the third oxide semiconductor pattern 1530, and the fourth oxide semiconductor pattern 1540 may be spaced apart from one another.

The first oxide semiconductor pattern 1510 disposed in each of the first to third pixel circuits PC1 to PC3 may have an isolated shape. The first oxide semiconductor pattern 1510 may have a shape extending in the second direction (e.g., the y direction). The first oxide semiconductor pattern 1510 of the first pixel circuit PC1 and the first oxide semiconductor pattern 1510 of the second pixel circuit PC2 may be symmetrically disposed with each other with respect to the virtual line IML1, and the first oxide semiconductor pattern 1510 of the second pixel circuit PC2 and the first oxide semiconductor pattern 1510 of the third pixel circuit PC3 may be symmetrically disposed with each other with respect to the virtual line IML2.

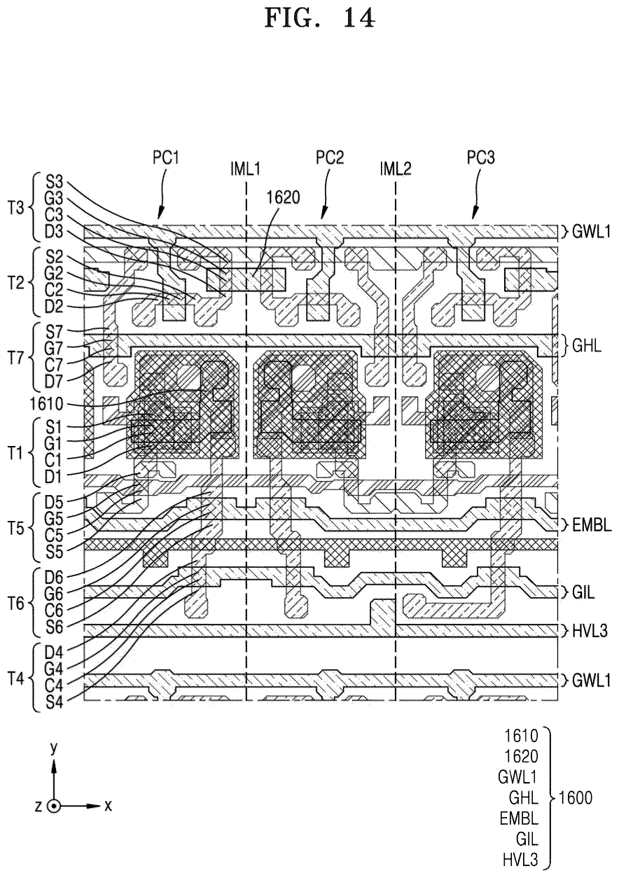

The first oxide semiconductor pattern 1510 may include the seventh semiconductor layer A7 of the seventh transistor T7 (see FIG. 7). The seventh semiconductor layer A7 may overlap a hold gate line GHL (see FIG. 14) of a fourth conductive layer 1600 (see FIG. 14) described below. An end of the first oxide semiconductor pattern 1510 may be electrically connected to the hold capacitor Chd (see FIG. 7) through an eleventh conductive pattern 1740 (see FIG. 15) described below. The other end of the first oxide semiconductor pattern 1510 may overlap the first horizontal reference voltage line HVRL1 and the second horizontal reference voltage line HVRL2 (see FIG. 15) and may be electrically connected to the second horizontal reference voltage line HVRL2 (see FIG. 15).

The second oxide semiconductor pattern 1520 disposed in each of the first to third pixel circuits PC1 to PC3 may have an isolated shape. The second oxide semiconductor pattern 1520 may be bent to approximately have an “L” shape. The second oxide semiconductor pattern 1520 of the first pixel circuit PC1 and the second oxide semiconductor pattern 1520 of the second pixel circuit PC2 may be symmetrically disposed with each other with respect to the virtual line IML1 described above, and the second oxide semiconductor pattern 1520 of the second pixel circuit PC2 and the second oxide semiconductor pattern 1520 of the third pixel circuit PC3 may be symmetrically disposed with each other with respect to the virtual line IML2.

The second oxide semiconductor pattern 1520 may include a second semiconductor layer A2 of the second transistor T2 (see FIG. 7) and a third semiconductor layer A3 of the third transistor T3 (see FIG. 7). For example, the second semiconductor layer A2 of the second transistor T2 (see FIG. 7) and the third semiconductor layer A3 of the third transistor T3 (see FIG. 7) may be integrally connected to each other. The second semiconductor layer A2 may overlap a first scan line GWL1 (see FIG. 14) described below, and the third semiconductor layer A3 may overlap a seventh conductive pattern 1620 (see FIG. 14) described below.

The third oxide semiconductor pattern 1530 disposed in each of the first to third pixel circuits PC1 to PC3 may have an isolated shape. The third oxide semiconductor pattern 1530 may have a shape extending in the second direction (e.g., the y direction). The third oxide semiconductor pattern 1530 of the first pixel circuit PC1 and the third oxide semiconductor pattern 1530 of the second pixel circuit PC2 may be symmetrically disposed with each other with respect to the virtual line IML1, and the third oxide semiconductor pattern 1530 of the second pixel circuit PC2 and the third oxide semiconductor pattern 1530 of the third pixel circuit PC3 may be symmetrically disposed with each other with respect to the virtual line IML2.

The third oxide semiconductor pattern 1530 may include the first semiconductor layer A1 of the first transistor T1 (see FIG. 7). The first semiconductor layer A1 may overlap the fourth conductive pattern 1410 (see FIG. 12) and a sixth conductive pattern 1610 (see FIG. 14) described below. The fourth conductive pattern 1410 (see FIG. 12) and the sixth conductive pattern 1610 (see FIG. 14) may form a dual gate structure of the first transistor T1 (see FIG. 7).

The fourth oxide semiconductor pattern 1540 disposed in each of the first to third pixel circuits PC1 to PC3 may have an isolated shape. The fourth oxide semiconductor pattern 1540 may have a shape extending in the second direction (e.g., the y direction). The fourth oxide semiconductor pattern 1540 of the first pixel circuit PC1 and the fourth oxide semiconductor pattern 1540 of the second pixel circuit PC2 may be symmetrically disposed with each other with respect to the virtual line IML1. However, the fourth oxide semiconductor pattern 1540 of the third pixel circuit PC3 may have an inverted “L” shape by further including a portion extending in the first direction (e.g., the x direction), unlike the fourth oxide semiconductor pattern 1540 of the first pixel circuit PC1.

The fourth oxide semiconductor pattern 1540 may include a fourth semiconductor layer A4 and a sixth semiconductor layer A6. For example, the fourth semiconductor layer A4 and the sixth semiconductor layer A6 may be integrally connected to each other. An end of the fourth oxide semiconductor pattern 1540 may overlap the third conductive pattern 1310 (see FIG. 11) and may be connected to a tenth conductive pattern 1730 (see FIG. 15) described below. The other end of the fourth oxide semiconductor pattern 1540 may overlap and may be connected to the horizontal initialization voltage line HVL (see FIG. 7). For example, the fourth oxide semiconductor pattern 1540 of the first pixel circuit PC1 may be connected to the first horizontal initialization voltage line HVL1 (see FIG. 7), the fourth oxide semiconductor pattern 1540 of the second pixel circuit PC2 may be connected to the second horizontal initialization voltage line HVL2 (see FIG. 7), and the fourth oxide semiconductor pattern 1540 of the third pixel circuit PC3 may be connected to the third horizontal initialization voltage line HVL3 (see FIG. 7).

Each of the first oxide semiconductor pattern 1510, the second oxide semiconductor pattern 1520, the third oxide semiconductor pattern 1530, and the fourth oxide semiconductor pattern 1540 may include a portion which is at least partially conductive. For example, a conduction process using plasma, etc. may be performed on at least a portion of each of the first oxide semiconductor pattern 1510, the second oxide semiconductor pattern 1520, the third oxide semiconductor pattern 1530, and the fourth oxide semiconductor pattern 1540.

Referring to FIG. 14, the fourth conductive layer 1600 may be disposed on the oxide semiconductor layer 1500. The fourth conductive layer 1600 may include Al, Pt, Pd, Ag, Mg, Au, Ni, Nd, Ir, Cr, Li, Ca, Mo, Ti, W, and/or Cu and may include a single layer or multi-layers including the materials described above.

The fourth conductive layer 1600 may include the first scan line GWL1, the hold gate line GHL, a second emission control line EMBL, an initialization gate line GIL, the third horizontal initialization voltage line HVL3, the sixth conductive pattern 1610, and the seventh conductive pattern 1620. The first scan line GWL1, the hold gate line GHL, the second emission control line EMBL, the initialization gate line GIL, the third horizontal initialization voltage line HVL3, the sixth conductive pattern 1610, and the seventh conductive pattern 1620 may be spaced apart from one another.

The first scan line GWL1 may extend in the first direction (e.g., the x direction) and may cross the first pixel circuit PC1, the second pixel circuit PC2, and the third pixel circuit PC3. The first scan line GWL1 may cross the pixel circuits disposed in the same row as the first pixel circuit PC1 and the second pixel circuit PC2. The first scan line GWL1 may overlap a second scan line GWL2 (see FIG. 15) described below and may be electrically connected to the second scan line GWL2 (see FIG. 15).

The first scan line GWL1 may include a stem portion extending in the first direction (e.g., the x direction) and a branch portion protruding from the stem portion and protruding in the second direction (e.g., the y direction). The branch portion of the first scan line GWL1 may include a portion overlapping the second oxide semiconductor pattern 1520 (see FIG. 13), for example, a second gate electrode G2 of the second transistor T2. Referring to FIGS. 13 and 14, the second semiconductor layer A2 of the second transistor T2 may include a channel area C2 overlapping the first scan line GWL1 and conductive areas S2 and D2 disposed at both sides of the channel area C2, respectively. One of the conductive areas S2 and D2 may be a source area, and the other may be a drain area. The source area and the drain area may correspond to a source electrode and a drain electrode, respectively. The positions of the source area and the drain area may be exchanged according to the characteristic of a transistor.

The hold gate line GHL may extend in the first direction (e.g., the x direction) and may cross the first pixel circuit PC1, the second pixel circuit PC2, and the third pixel circuit PC3. The hold gate line GHL may cross the pixel circuits disposed in the same row as the first pixel circuit PC1 and the second pixel circuit PC2.

The hold gate line GHL may include a portion overlapping the first oxide semiconductor pattern 1510 (see FIG. 13), for example, the seventh gate electrode G7 of the seventh transistor T7. Referring to FIGS. 13 and 14, the seventh semiconductor layer A7 of the seventh transistor T7 may include the channel area C7 overlapping the hold gate line GHL and the conductive areas S7 and D7 disposed at both sides of the channel C7, respectively. One of the conductive areas S7 and D7 may be a source area, and the other may be a drain area. The source area and the drain area may correspond to a source electrode and a drain electrode, respectively. The positions of the source area and the drain area may be exchanged according to the characteristic of a transistor.

The second emission control line EMBL may extend in the first direction (e.g., the x direction) and may cross the first pixel circuit PC1, the second pixel circuit PC2, and the third pixel circuit PC3. The second emission control line EMBL may cross the pixel circuits disposed in the same row as the first pixel circuit PC1 and the second pixel circuit PC2.

The second emission control line EMBL may include a portion overlapping the fourth oxide semiconductor pattern 1540 (see FIG. 13), for example, a sixth gate electrode G6 of the sixth transistor T6. Referring to FIGS. 13 and 14, the sixth semiconductor layer A6 of the sixth transistor T6 may include a channel area C6 overlapping the second emission control line EMBL and conductive areas S6 and D6 disposed at both sides of the channel C6, respectively. One of the conductive areas S6 and D6 may be a source area, and the other may be a drain area. The source area and the drain area may correspond to a source electrode and a drain electrode, respectively. The positions of the source area and the drain area may be exchanged according to the characteristic of a transistor.

The initialization gate line GIL may extend in the first direction (e.g., the x direction) and may cross the first pixel circuit PC1, the second pixel circuit PC2, and the third pixel circuit PC3. The initialization gate line GIL may cross the pixel circuits disposed in the same row as the first pixel circuit PC1 and the second pixel circuit PC2.

The initialization gate line GIL may include a portion overlapping the fourth oxide semiconductor pattern 1540 (see FIG. 13), for example, a fourth gate electrode G4 of the fourth transistor T4. Referring to FIGS. 13 and 14, the fourth semiconductor layer A4 of the fourth transistor T4 may include a channel area C4 overlapping the initialization gate line GIL and conductive areas S4 and D4 disposed at both sides of the channel C4, respectively. One of the conductive areas S4 and D4 may be a source area, and the other may be a drain area. The source area and the drain area may correspond to a source electrode and a drain electrode, respectively. The positions of the source area and the drain area may be exchanged according to the characteristic of a transistor.

The third horizontal initialization voltage line HVL3 may extend in the first direction (e.g., the x direction) and may cross the first pixel circuit PC1, the second pixel circuit PC2, and the third pixel circuit PC3. The third horizontal initialization voltage line HVL3 may cross the pixel circuits disposed in the same row as the first pixel circuit PC1 and the second pixel circuit PC2. The third horizontal initialization voltage line HVL3 may be connected to the fourth oxide semiconductor pattern 1540 (see FIG. 13) of the third pixel circuit PC3 through a fourteenth conductive pattern 1770 (see FIG. 15) described below.

The sixth conductive pattern 1610 disposed in each of the first to third pixel circuits PC1 to PC3 may have an isolated shape. The sixth conductive pattern 1610 of the first pixel circuit PC1 may be symmetrically disposed with the sixth conductive pattern 1610 of the second pixel circuit PC2 with respect to the virtual line IML1, and the sixth conductive pattern 1610 of the second pixel circuit PC2 may be symmetrically disposed with the sixth conductive pattern 1610 of the third pixel circuit PC3 with respect to the virtual line IML2.

The sixth conductive pattern 1610 of each of the first to third pixel circuits PC1 to PC3 may include the first gate electrode G1 of the first transistor T1. Referring to FIGS. 13 and 14, the first semiconductor layer A1 of the first transistor T1 may include the channel area C1 overlapping the sixth conductive pattern 1610 and the conductive areas S1 and D1 disposed at both sides of the channel C1, respectively. One of the conductive areas S1 and D1 may be a source area, and the other may be a drain area. The source area and the drain area may correspond to a source electrode and a drain electrode, respectively. The positions of the source area and the drain area may be exchanged according to the characteristic of a transistor. Here, a portion of the fourth conductive pattern 1410 (see FIG. 12) and the first gate electrode G1 may overlap each other with the channel area C1 therebetween. A portion of the fourth conductive pattern 1410 (see FIG. 12), the portion overlapping the channel area C1 of the first transistor T1, may correspond to the first lower gate electrode G1b (see FIG. 8) of the first transistor T1.

The seventh conductive pattern 1620 may have an isolated shape and may have a shape extending in the first direction (e.g., the x direction). The seventh conductive pattern 1620 may be disposed across the first pixel circuit PC1 and the second pixel circuit PC2. The seventh conductive pattern 1620 may cross the virtual line IML1. Likewise, the seventh conductive pattern 1620 may be disposed across the third pixel circuit PC3 and the first pixel circuit PC1. However, the seventh conductive pattern 1620 might not be disposed across the second pixel circuit PC2 and the third pixel circuit PC3. For example, the seventh conductive pattern 1620 might not be disposed on the virtual line IML2 which is an edge between the second pixel circuit PC2 and the third pixel circuit PC3.

The seventh conductive pattern 1620 of each of the first to third pixel circuits PC1 to PC3 may include a third gate electrode G3 of the third transistor T3. Referring to FIGS. 13 and 14, the third semiconductor layer A3 of the third transistor T3 may include a channel area C3 overlapping the seventh conductive pattern 1620 and conductive areas S3 and D3 disposed at both sides of the channel C3, respectively. One of the conductive areas S3 and D3 may be a source area, and the other may be a drain area. The source area and the drain area may correspond to a source electrode and a drain electrode, respectively. The positions of the source area and the drain area may be exchanged according to the characteristic of a transistor.

Referring to FIG. 15, a fifth conductive layer 1700 may be disposed on the fourth conductive layer 1600. The fifth conductive layer 1700 may include Al, Pt, Pd, Ag, Mg, Au, Ni, Nd, Ir, Cr, Li, Ca, Mo, Ti, W, and/or Cu and may include a single layer or multi-layers including the materials described above.

The fifth conductive layer 1700 may include the second scan line GWL2, the second horizontal reference voltage line HVRL2, a reference gate line GRL, a horizontal driving voltage line HPL, the first horizontal initialization voltage line HVL1, the second horizontal initialization voltage line HVL2, a common voltage line VSL, and eighth to fourteenth conductive patterns 1710, 1720, 1730, 1740, 1750, 1760, and 1770. The second scan line GWL2, the second horizontal reference voltage line HVRL2, the reference gate line GRL, the horizontal driving voltage line HPL, the first horizontal initialization voltage line HVL1, the second horizontal initialization voltage line HVL2, the common voltage line VSL, and the eighth to fourteenth conductive patterns 1710 to 1770 may be spaced apart from one another.

The second scan line GWL2 may extend in the first direction (e.g., the x direction) and may cross the first pixel circuit PC1, the second pixel circuit PC2, and the third pixel circuit PC3. The second scan line GWL2 may cross the pixel circuits disposed in the same row as the first pixel circuit PC1, the second pixel circuit PC2, and the third pixel circuit PC3. The second scan line GWL2 may overlap the first scan line GWL1 (see FIG. 14) and may be electrically connected to the first scan line GWL1 (see FIG. 14) through a first contact hole CNT1.

The second horizontal reference voltage line HVRL2 may extend in the first direction (e.g., the x direction) and may cross the first pixel circuit PC1, the second pixel circuit PC2, and the third pixel circuit PC3. The second horizontal reference voltage line HVRL2 may cross the pixel circuits disposed in the same row as the first pixel circuit PC1, the second pixel circuit PC2, and the third pixel circuit PC3. The second horizontal reference voltage line HVRL2 may overlap the first horizontal reference voltage line HVRL1 (see FIG. 9).

The second horizontal reference voltage line HVRL2 may be electrically connected to the first horizontal reference voltage line HVRL1 (see FIG. 9) through a second contact hole CNT2. Also, the second horizontal reference voltage line HVRL2 may be connected to the second oxide semiconductor pattern 1520 (see FIG. 13) through a fourth contact hole CNT4 and may transmit a reference voltage to the third transistor T3 (see FIG. 14). The second horizontal reference voltage line HVRL2 may be connected to the first oxide semiconductor pattern 1510 (see FIG. 13) through a fifth contact hole CNT5 and may transmit a reference voltage to the seventh transistor T7 (see FIG. 14).

The reference gate line GRL may extend in the first direction (e.g., the x direction) and may cross the first pixel circuit PC1, the second pixel circuit PC2, and the third pixel circuit PC3. The reference gate line GRL may cross the pixel circuits disposed in the same row as the first pixel circuit PC1, the second pixel circuit PC2, and the third pixel circuit PC3. The reference gate line GRL may be electrically connected to the seventh conductive pattern 1620 (see FIG. 14) through a sixth contact hole CNT6 and may transmit a reference signal to a gate electrode of the third transistor T3 (see FIG. 14).

The eighth conductive pattern 1710 located in each of the first to third pixel circuits PC1 to PC3 may have an isolated shape. The eighth conductive pattern 1710 of the first pixel circuit PC1 may be symmetrically disposed with the eighth conductive pattern 1710 of the second pixel circuit PC2 with respect to the virtual line IML1, and the eighth conductive pattern 1710 of the second pixel circuit PC2 may be symmetrically disposed with the eighth conductive pattern 1710 of the third pixel circuit PC3 with respect to the virtual line IML2.

The eighth conductive pattern 1710 may be a connection electrode connecting the second oxide semiconductor pattern 1520 (see FIG. 13) including the second semiconductor layer A2 (see FIG. 13) to the data line DL (see FIG. 16). The eighth conductive pattern 1710 may be connected to an end of the second oxide semiconductor pattern 1520 (see FIG. 13) through a seventh contact hole CNT7.

The ninth conductive pattern 1720 located in each of the first to third pixel circuits PC1 to PC3 may have an isolated shape. The ninth conductive pattern 1720 of the first pixel circuit PC1 may be symmetrically disposed with the ninth conductive pattern 1720 of the second pixel circuit PC2 with respect to the virtual line IML1, and the ninth conductive pattern 1720 of the second pixel circuit PC2 may be symmetrically disposed with the ninth conductive pattern 1720 of the third pixel circuit PC3 with respect to the virtual line IML2.

The ninth conductive pattern 1720 may be a connection electrode connecting the second oxide semiconductor pattern 1520 (see FIG. 13) including the second semiconductor layer A2 (see FIG. 13) and the third semiconductor layer A3 (see FIG. 13) to the sixth conductive pattern 1610 (see FIG. 14) including the first gate electrode G1 (see FIG. 14) of the first transistor T1 (see FIG. 14). For example, the ninth conductive pattern 1720 may be the first node electrode N1 connecting the first transistor T1 (see FIG. 14), the second transistor T2 (see FIG. 14), and the third transistor T3 (see FIG. 14). The ninth conductive pattern 1720 may be connected to the second oxide semiconductor pattern 1520 (see FIG. 13) through an eighth contact hole CNT8 and may be connected to the sixth conductive pattern 1610 (see FIG. 14) through a ninth contact hole CNT9. Also, the ninth conductive pattern 1720 may be electrically connected to the storage capacitor Cst (see FIG. 7). The ninth conductive pattern 1720 may be connected to the first storage electrode CEs1 (see FIG. 10) of the storage capacitor Cst (see FIG. 7) through a tenth contact hole CNT10.

The tenth conductive pattern 1730 located in each of the first to third pixel circuits PC1 to PC3 may have an isolated shape. The tenth conductive pattern 1730 may overlap the third conductive pattern 1310 (see FIG. 11). The tenth conductive pattern 1730 of the first pixel circuit PC1 may be symmetrically disposed with the tenth conductive pattern 1730 of the second pixel circuit PC2 with respect to the virtual line IML1, and the tenth conductive pattern 1730 of the second pixel circuit PC2 may be symmetrically disposed with the tenth conductive pattern 1730 of the third pixel circuit PC3 with respect to the virtual line IML2.

The tenth conductive pattern 1730 may be a connection electrode connecting the third oxide semiconductor pattern 1530 (see FIG. 13) including the first semiconductor layer A1 (see FIG. 13) to the fourth oxide semiconductor pattern 1540 (see FIG. 13) including the sixth semiconductor layer A6 (see FIG. 13). For example, the tenth conductive pattern 1730 may be the second node electrode N2 connecting the first transistor T1 (see FIG. 14) with the sixth transistor T6 (see FIG. 14). The tenth conductive pattern 1730 may be connected to the third oxide semiconductor pattern 1530 (see FIG. 13) through an eleventh contact hole CNT11 and may be connected to the fourth oxide semiconductor pattern 1540 (see FIG. 13) through a twelfth contact hole CNT12.

Also, the tenth conductive pattern 1730 may be electrically connected to the storage capacitor Cst (see FIG. 7), the hold capacitor Chd (see FIG. 7), and the first lower gate electrode G1b (see FIG. 8) of the first transistor T1 (see FIG. 14). The tenth conductive pattern 1730 may be electrically connected to the third conductive pattern 1310 (see FIG. 11) including the second storage electrode CEs2 (see FIG. 11) and the second hold electrode CEh2 (see FIG. 11) through a thirteenth contact hole CNT13. The tenth conductive pattern 1730 may be electrically connected to the fourth conductive pattern 1410 (see FIG. 12) including the first lower gate electrode G1b (see FIG. 8) through a fourteenth contact hole CNT14.

The eleventh conductive pattern 1740 located in each of the first to third pixel circuits PC1 to PC3 may have an isolated shape. The eleventh conductive pattern 1740 may have a shape extending in the second direction (e.g., the y direction). The eleventh conductive pattern 1740 of the first pixel circuit PC1 may be symmetrically disposed with the eleventh conductive pattern 1740 of the second pixel circuit PC2 with respect to the virtual line IML1, and the eleventh conductive pattern 1740 of the second pixel circuit PC2 may be symmetrically disposed with the eleventh conductive pattern 1740 of the third pixel circuit PC3 with respect to the virtual line IML2.

The eleventh conductive pattern 1740 may be a connection electrode connecting the first hold electrode CEh1 (see FIG. 10) of the hold capacitor Chd (see FIG. 7) to the first oxide semiconductor pattern 1510 (see FIG. 13) including the seventh semiconductor layer A7 (see FIG. 13). An end of the eleventh conductive pattern 1740 may be electrically connected to the second conductive pattern 1220 (see FIG. 10) including the first hold electrode CEh1 (see FIG. 10) through a fifteenth contact hole CNT15. The other end of the eleventh conductive pattern 1740 may be electrically connected to the first oxide semiconductor pattern 1510 (see FIG. 13) through a sixteenth contact hole CNT16.

The twelfth conductive pattern 1750 located in each of the first to third pixel circuits PC1 to PC3 may have an isolated shape. The twelfth conductive pattern 1750 may have a shape extending in the first direction (e.g., the x direction). The twelfth conductive pattern 1750 of the first pixel circuit PC1 may be symmetrically disposed with the twelfth conductive pattern 1750 of the second pixel circuit PC2 with respect to the virtual line IML1, and the twelfth conductive pattern 1750 of the second pixel circuit PC2 may be symmetrically disposed with the twelfth conductive pattern 1750 of the third pixel circuit PC3 with respect to the virtual line IML2.

The twelfth conductive pattern 1750 may be a connection electrode connecting the third oxide semiconductor pattern 1530 (see FIG. 13) including the first semiconductor layer A1 (see FIG. 13) to the first silicon semiconductor pattern 1110 (see FIG. 9) including the fifth semiconductor layer A5 (see FIG. 9). An end of the twelfth conductive pattern 1750 may be electrically connected to the third oxide semiconductor pattern 1530 (see FIG. 13) through a seventeenth contact hole CNT17, and the other end of the twelfth conductive pattern 1750 may be electrically connected to the first silicon semiconductor pattern 1110 (see FIG. 9) through an eighteenth contact hole CNT18.

The horizontal driving voltage line HPL may extend in the first direction (e.g., the x direction) and may cross the first pixel circuit PC1, the second pixel circuit PC2, and the third pixel circuit PC3. The horizontal driving voltage line HPL may cross the pixel circuits disposed in the same row as the first pixel circuit PC1, the second pixel circuit PC2, and the third pixel circuit PC3. The horizontal driving voltage line HPL may be electrically connected to the first silicon semiconductor pattern 1110 (see FIG. 9) through a nineteenth contact hole CNT19 and may transmit a driving voltage to the fifth transistor T5 (see FIG. 10).

The thirteenth conductive pattern 1760 located in each of the first to third pixel circuits PC1 to PC3 may have an isolated shape. The thirteenth conductive pattern 1760 may have a shape extending in the first direction (e.g., the x direction). The thirteenth conductive pattern 1760 may overlap the repair line RPL. The thirteenth conductive pattern 1760 of the first pixel circuit PC1 and the thirteenth conductive pattern 1760 of the second pixel circuit PC2 may be symmetrically disposed with each other with respect to the virtual line IML1. The thirteenth conductive pattern 1760 of the third pixel circuit PC3 may include the same shape as the thirteenth conductive pattern 1760 of the first pixel circuit PC1 and may further include a protrusion portion extending therefrom in a diagonal direction.

The thirteenth conductive pattern 1760 may be a connection electrode connecting the fourth oxide semiconductor pattern 1540 (see FIG. 13) including the fourth semiconductor layer A4 (see FIG. 13) and the sixth semiconductor layer A6 (see FIG. 13) to the light-emitting diode LED (see FIG. 8). The thirteenth conductive pattern 1760 may be electrically connected to the fourth oxide semiconductor pattern 1540 (see FIG. 3) through a twentieth contact hole CNT20 and may be electrically connected to the repair line RPL (see FIG. 11) through a twenty-first contact hole CNT21.

The first horizontal initialization voltage line HVL1 and the second horizontal initialization voltage line HVL2 may extend in the first direction (e.g., the x direction) and may cross the first to third pixel circuits PC1 to PC3. The first horizontal initialization voltage line HVL1 and the second horizontal initialization voltage line HVL2 may cross the pixel circuits disposed in the same row as the first to third pixel circuits PC1 to PC3. The first horizontal initialization voltage line HVL1 may be electrically connected to the fourth oxide semiconductor pattern 1540 (see FIG. 13) of the first pixel circuit PC1 through a twenty-second contact hole CNT22 and may transmit an initialization voltage to the fourth transistor T4 (see FIG. 14) of the first pixel circuit PC1. The second horizontal initialization voltage line HVL2 may be electrically connected to the fourth oxide semiconductor pattern 1540 (see FIG. 13) of the second pixel circuit PC2 through a twenty-third contact hole CNT23 and may transmit an initialization voltage to the fourth transistor T4 (see FIG. 14) of the second pixel circuit PC2.

The fourteenth conductive pattern 1770 may have an isolated shape and may be disposed on the virtual line IML2 which is an edge between the second pixel circuit PC2 and the third pixel circuit PC3. The fourteenth conductive pattern 1770 may have a shape extending in the first direction (e.g., the x direction). The fourteenth conductive pattern 1770 may be a connection electrode connecting the fourth oxide semiconductor pattern 1540 (see FIG. 13) of the third pixel circuit PC3 to the third horizontal initialization voltage line HVL3 (see FIG. 14). The fourteenth conductive pattern 1770 may be electrically connected to the third horizontal initialization voltage line HVL3 (see FIG. 14) through a twenty-fourth contact hole CNT24 and may be electrically connected to the fourth oxide semiconductor pattern 1540 (see FIG. 13) of the third pixel circuit PC3 through a twenty-fifth contact hole CNT25 and may transmit an initialization voltage to the fourth transistor T4 (see FIG. 14) of the third pixel circuit PC3.

The common voltage line VSL may extend in the first direction (e.g., the x direction) and may cross the first pixel circuit PC1, the second pixel circuit PC2, and the third pixel circuit PC3. The common voltage line VSL may cross the pixel circuits disposed in the same row as the first pixel circuit PC1, the second pixel circuit PC2, and the third pixel circuit PC3. The common voltage line VSL may be electrically connected to the second power supply line 16 (see FIG. 6) disposed in the peripheral area PA (see FIG. 6) and may transmit a common voltage to the light-emitting diode LED (see FIG. 8).

Referring to FIG. 16, a sixth conductive layer 1800 may be disposed on the fifth conductive layer 1700. The sixth conductive layer 1800 may include Al, Pt, Pd, Ag, Mg, Au, Ni, Nd, Ir, Cr, Li, Ca, Mo, Ti, W, and/or Cu and may include a single layer or multi-layers including the materials described above.

The sixth conductive layer 1800 may include a data line DL, a vertical driving voltage line VPL, a vertical initialization voltage line VVL, a vertical reference voltage line VRL, a fifteenth conductive pattern 1810, and a sixteenth conductive pattern 1820. The data line DL, the vertical driving voltage line VPL, the vertical initialization voltage line VVL, the vertical reference voltage line VRL, the fifteenth conductive pattern 1810, and the sixteenth conductive pattern 1820 may be spaced apart from one another.

The data line DL may extend in the second direction (e.g., the y direction). The data line DL may include a first data line DL1 electrically connected to the first pixel circuit PC1, a second data line DL2 electrically connected to the second pixel circuit PC2, and a third data line DL3 electrically connected to the third pixel circuit PC3. The data line DL may be electrically connected to the eighth conductive pattern 1710 (see FIG. 15) connected to the second oxide semiconductor pattern 1520 (see FIG. 13) through a twenty-sixth contact hole CNT26. For example, the data line DL may transmit a data signal to the second semiconductor layer A2 (see FIG. 13) through the eighth conductive pattern 1710.

The first data line DL1 may cross the first pixel circuit PC1, the second data line DL2 may cross the second pixel circuit PC2, and the third data line DL3 may cross the third pixel circuit PC3 except for a portion thereof. The first data line DL1 may be disposed at the left side of the first vertical driving voltage line VPL1. The second data line DL2 and the third data line DL3 may be disposed in parallel with each other between the second vertical driving voltage line VPL2 and the vertical reference voltage line VVRL.

The vertical driving voltage line VPL may extend in the second direction (e.g., the y direction). The vertical driving voltage line VPL may include a first vertical driving voltage line VPL1 disposed at the first pixel circuit PC1 and a second vertical driving voltage line VPL2 disposed at the second pixel circuit PC2. The first vertical driving voltage line VPL1 and the second vertical driving voltage line VPL2 may be symmetrically disposed with each other with respect to the virtual line IML1. The first vertical driving voltage line VPL1 may be electrically connected to the horizontal driving voltage line HPL (see FIG. 15) through a twenty-seventh-1 contact hole CNT27a, and the second vertical driving voltage line VPL2 may be electrically connected to the horizontal driving voltage line HPL (see FIG. 15) through a twenty-seventh-2 contact hole CNT27b.

The vertical initialization voltage line VVL may extend in the second direction (e.g., the y direction). The vertical initialization voltage line VVL may be disposed between the first vertical driving voltage line VPL1 and the second vertical driving voltage line VPL2. The vertical initialization voltage line VVL may be disposed on the virtual line IML1 which is an edge between the first pixel circuit PC1 and the second pixel circuit PC2. The vertical initialization voltage line VVL may be electrically connected to the second horizontal initialization voltage line HVL2 (see FIG. 15) through a twenty-eighth contact hole CNT28.

The vertical reference voltage line VVRL may extend in the second direction (e.g., the y direction). The vertical reference voltage line VVRL may be disposed at the third pixel circuit PC3. The vertical reference voltage line VVRL may be electrically connected to the second horizontal reference voltage line HVRL2 (see FIG. 15) through a twenty-ninth contact hole CNT29.

Each of the fifteenth conductive pattern 1810 and the sixteenth conductive pattern 1820 may have an isolated shape. Each of the fifth conductive pattern 1810 and the sixteenth conductive pattern 1820 may be disposed in each of the first to third pixel circuits PC1 to PC3. The fifteenth conductive pattern 1810 may be electrically connected to the tenth conductive pattern 1730 (see FIG. 15) through a thirtieth contact hole CNT30 and may have a shape extending in the second direction (e.g., the y direction) to cover the ninth conductive pattern 1720 (see FIG. 15). The fifteenth conductive pattern 1810 may shield the ninth conductive pattern 1720 (see FIG. 15) electrically connected to the storage capacitor Cst, and thus, the image quality characteristic may be improved. The sixteenth conductive pattern 1820 may be a connection electrode connecting the fourth oxide semiconductor pattern 1540 (see FIG. 13) to the light-emitting diode LED (see FIG. 8). The sixteenth conductive pattern 1820 may be electrically connected to the thirteenth conductive pattern 1760 (see FIG. 15) through a thirty-first contact hole CNT31 and may be electrically connected to the pixel electrode 210 (see FIG. 8) of the light-emitting diode LED (see FIG. 8) through a thirty-second contact hole CNT32.

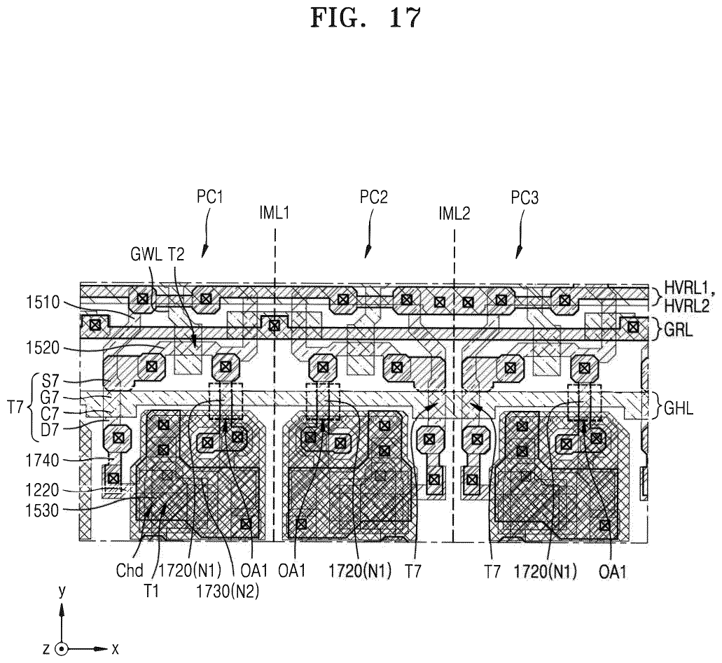

FIG. 17 is an enlarged plan view of a portion of a display panel according to an embodiment. For convenience of explanation, FIG. 17 illustrates a structure in which only the silicon semiconductor layer 1100 (see FIG. 9), the first conductive layer 1200 (see FIG. 10), the second conductive layer 1300 (see FIG. 11), the third conductive layer 1400 (see FIG. 12), the oxide semiconductor layer 1500 (see FIG. 13), the fourth conductive layer 1600 (see FIG. 14), and the fifth conductive layer 1700 (see FIG. 15) are stacked.

Referring to FIG. 17, the hold gate line GHL may extend in a first direction (e.g., an x direction). A portion of the hold gate line GHL may overlap the first oxide semiconductor pattern 1510, and the portion of the hold gate line GHL overlapping the first oxide semiconductor pattern 1510 may be the seventh gate electrode G7 of the seventh transistor T7. A portion of the first oxide semiconductor pattern 1510, the portion overlapping the hold gate line GHL, may be the channel area C7 of the seventh transistor T7. An end of the first oxide semiconductor pattern 1510 may be connected to the second horizontal reference voltage line HVRL2, so that the seventh transistor T7 may receive a reference voltage. The other end of the first oxide semiconductor pattern 1510 may be electrically connected to the first hold electrode CEh1 (see FIG. 10) of the hold capacitor Chd included in the second conductive pattern 1220, through the eleventh conductive pattern 1740.

According to an embodiment, the hold gate line GHL may cross between the first transistor T1 and the second transistor T2 in a plan view. For example, the hold gate line GHL may cross between the third oxide semiconductor pattern 1530 in which the first semiconductor layer A1 (see FIG. 13) is disposed and the second oxide semiconductor pattern 1520 in which the second semiconductor layer A2 (see FIG. 13) is disposed, in the plan view.

The hold gate line GHL may cross between the first transistor T1 and the second transistor T2, and thus, the hold gate line GHL may overlap the connection electrode connecting the first transistor T1 to the second transistor T2. For example, the hold gate line GHL may include a first overlapping area OA1 overlapping the ninth conductive pattern 1720. Here, the ninth conductive pattern 1720 may be the first node electrode N1 connecting the first gate electrode G1 (see FIG. 14) of the first transistor T1 with the second semiconductor layer A2 (see FIG. 13).

The display panel, according to an embodiment, may include the seventh transistor T7 connected to the hold capacitor Chd and the hold gate line GHL, and thus, may adjust the hold capacitor Chd through a hold signal transmitted through the hold gate line GHL. The hold capacitor Chd may have a large capacity of about 100 fF, and thus, when the hold capacitor Chd operates in an emission section, the hold capacitor Chd may cause a deleterious effect on the second node electrode N2 electrically connected thereto. In addition, the second node electrode N2 may also be connected also to the first node electrode N1 through the storage capacitor Cst (see FIG. 7), and thus, when the hold capacitor Chd is seen in the emission section, the image quality characteristic of the display panel 10 (see FIG. 2) may be degraded.

Here, as illustrated in FIG. 17, when the display panel includes the seventh transistor T7 connected to the hold capacitor Chd and the hold gate line GHL, the hold capacitor Chd may be adjusted to be formed only in a data write section and a compensation section and to be blocked in an emission section. When the hold capacitor Chd is blocked in the emission section, the voltages of the second node electrode N2 and the first node electrode N1 may further be maintained to be stable, and thus, coupling of the pixel circuits may further become robust. For example, when the display panel includes the seventh transistor T7 and the hold gate line GHL, the brightness difference between pixels may be small, even when noise occurs in a data voltage due to other parameters, and thus, the display panel may stably realize a high-quality image.

Also, as the hold gate line GHL extends in the first direction (e.g., the x direction), the hold gate line GHL may inevitably and partially overlap a node electrode of the first transistor T1. For example, as illustrated in FIG. 17, when the hold gate line GHL crosses between the first transistor T1 and the second transistor T2, the hold gate line GHL may overlap the first node electrode N1. As an overlapping area of the hold gate line GHL and the node electrode increases, the voltage of the node electrode may become unstable due to the coupling and defects such as the ghost mura may occur.

However, when the hold gate line GHL includes only a first overlapping area OA1 overlapping the first node electrode N1, as illustrated in FIG. 17, the overlapping area of the hold gate line GHL and the node electrode may be relatively less, compared to the overlapping area in the case of a structure in which the hold gate line GHL overlaps a plurality of node electrodes. For example, in the display panel according to an embodiment, the hold gate line GHL may cross between the first transistor T1 and the second transistor T2, and thus, the overlapping area of the hold gate line GHL and the node electrode may be minimized. Thus, defects such as the ghost mura due to coupling may be prevented and a high quality image may be realized.

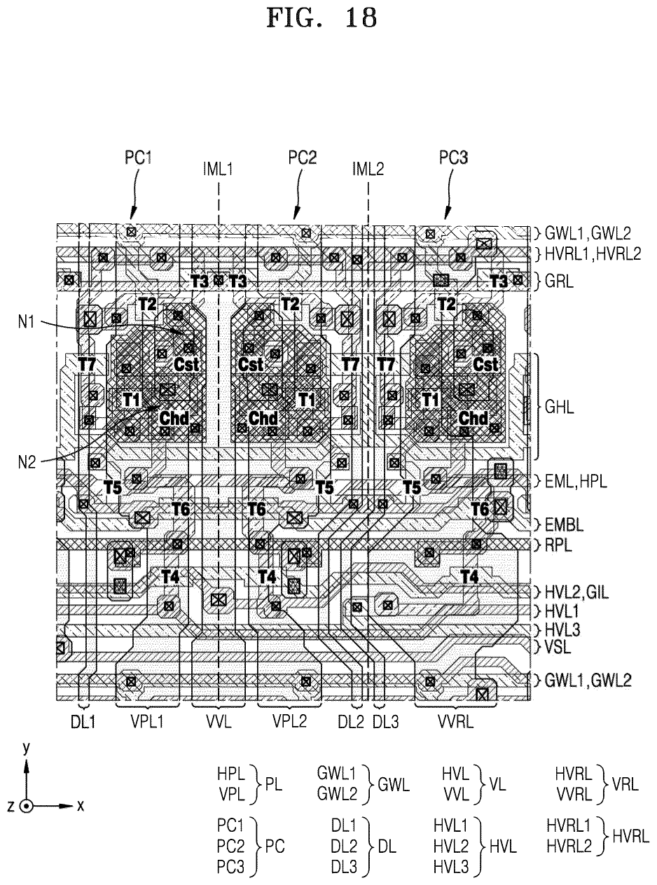

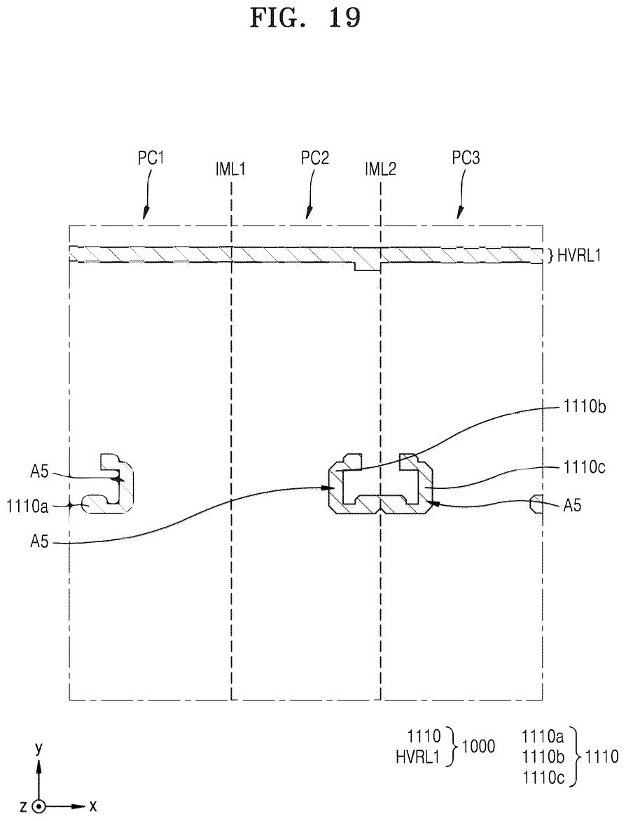

FIG. 18 is a schematic plan view of pixel circuits of a display panel according to an embodiment. FIGS. 19 to 26 are plan views for showing a process of forming a pixel circuit of a display panel according to an embodiment. Referring to FIGS. 18 to 26, the aspects may be the same as described with reference to FIGS. 7 to 17, except for the aspects with respect to the hold gate line GHL and the seventh transistor T7. For the elements of FIGS. 18 to 26, indicated by the same reference numerals as the elements of FIGS. 7 to 17, the descriptions of FIGS. 7 to 17 may be referred to, and hereinafter, different aspects are mainly described and to the extent that an element is not described in detail with respect to this figure, it may be understood that the element is at least similar to a corresponding element that has been described elsewhere within the present disclosure.

First, referring to FIG. 18, each of first to third pixel circuits PC1 to PC3 may include transistors and a capacitor. According to an embodiment, each of the first to third pixel circuits PC1 to PC3 may include first to seventh transistors T1 to T7, a storage capacitor Cst, and a hold capacitor Chd.

Each of the first to third pixel circuits PC1 to PC3 may be electrically connected to gate lines configured to transmit signals to a gate of each of the first to seventh transistors T1 to T7. For example, the pixel circuit PC may be connected to a scan line GWL configured to transmit a scan signal, an initialization gate line GBL configured to transmit an initialization signal, a reference gate line GRL configured to transmit a reference signal, a first emission control line EML configured to transmit a first emission control signal, a second emission control line EMBL configured to transmit a second emission control signal, a hold gate line GHL configured to transmit a hold signal, and a data line DL configured to transmit a data line. Also, each of the first to third pixel circuits PC1 to PC3 may be connected to a driving voltage line PL configured to transmit a driving voltage, a reference voltage line VRL configured to transmit a reference voltage, and an initialization voltage line VL configured to transmit an initialization voltage.

Referring to FIG. 19, a silicon semiconductor layer 1100 may be disposed on a substrate. The silicon semiconductor layer 1100 may include a first silicon semiconductor pattern 1110 and a first horizontal reference voltage line HVRL1.

The first silicon semiconductor pattern 1100 may include a first-1 silicon semiconductor pattern 1110a disposed in the first pixel circuit PC1, a first-2 silicon semiconductor pattern 1110b disposed in the second pixel circuit PC2, and a first-3 silicon semiconductor pattern 1110c disposed in the third pixel circuit PC3. The first-1 silicon semiconductor pattern 1110a may have an isolated shape and may include a curved portion. The first-2 silicon semiconductor pattern 1110b and the first-3 silicon semiconductor pattern 1110c may be connected with each other to be integrally formed. Each of the first-1 silicon semiconductor pattern 1110a, the first-2 silicon semiconductor pattern 1110b, and the first-3 silicon semiconductor pattern 1110c may include a fifth semiconductor layer A5.

The first horizontal reference voltage line HVRL1 may extend in a first direction (e.g., an x direction) and may cross the first pixel circuit PC1, the second pixel circuit PC2, and the third pixel circuit PC3.

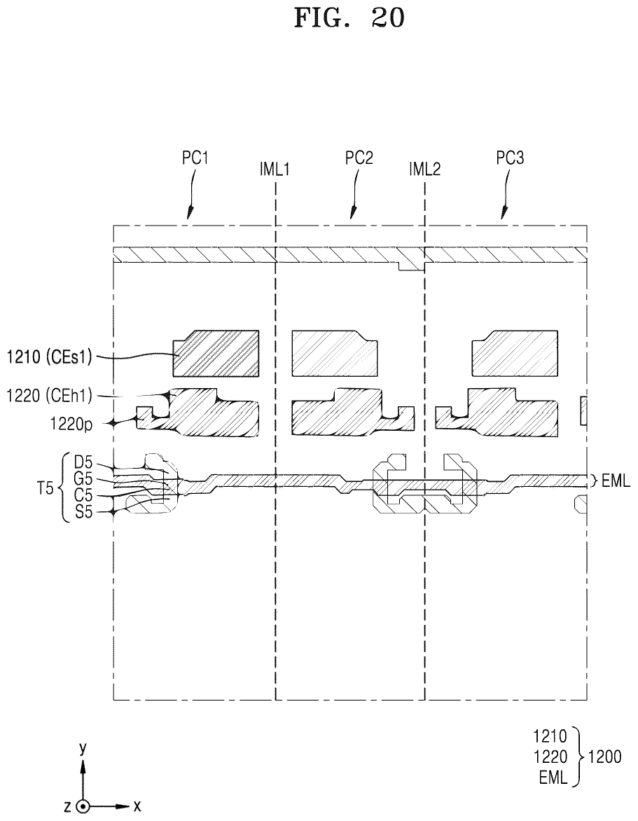

Referring to FIG. 20, a first conductive layer 1200 may be disposed on the silicon semiconductor layer 1100. The first conductive layer 1200 may include a first emission control line EML, a first conductive pattern 1210, and a second conductive pattern 1220.

The first emission control line EML may extend in the first direction (e.g., the x direction) and may cross the first pixel circuit PC1, the second pixel circuit PC2, and the third pixel circuit PC3. The first emission control line EML may include a fifth gate electrode G5 of the fifth transistor T5 of each of the first to third pixel circuits PC1 to PC3. The fifth semiconductor layer A5 (see FIG. 19) of the fifth transistor T5 may include a channel area C5 overlapping the fifth gate electrode G5 and doping areas S5 and D5 disposed at both sides of the channel area C5, respectively, and doped with impurities.

The first conductive pattern 1210 and the second conductive pattern 1220 disposed in each of the first to third pixel circuits PC1 to PC3 may have isolated shapes. The first conductive pattern 1210 may include a first storage electrode CEs1 of the storage capacitor Cst (see FIG. 18). The second conductive pattern 1220 may include a first hold electrode CEh1 of the hold capacitor Chd (see FIG. 18). Here, the second conductive pattern 1220 may further include a protrusion portion 1220p to be connected to the seventh transistor T7 (see FIG. 18).

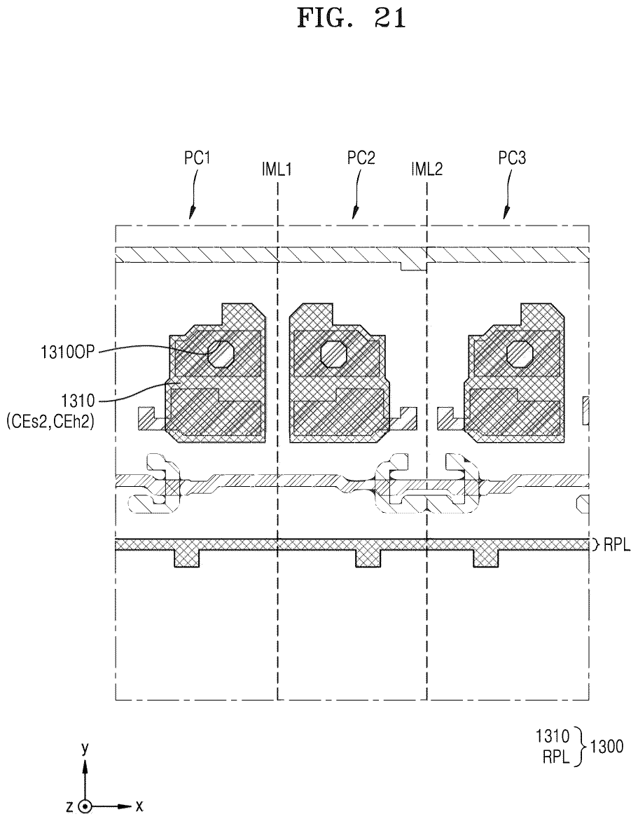

Referring to FIG. 21, a second conductive layer 1300 may be disposed on the first conductive layer 1200. The second conductive layer 1300 may include a repair line RPL and a third conductive pattern 1310.

The repair line RPL may extend in the first direction (e.g., the x direction) and may cross the first pixel circuit PC1, the second pixel circuit PC2, and the third pixel circuit PC3.

The third conductive pattern 1310 disposed in each of the first to third pixel circuits PC1 to PC3 may have an isolated shape. The third conductive pattern 1310 may overlap each of the first conductive pattern 1210 (see FIG. 20) and the second conductive pattern 1220 (see FIG. 20) of the first conductive layer 1200 (see FIG. 20). The third conductive pattern 1310 may include a second storage electrode CEs2 of the storage capacitor Cst (see FIG. 18) and a second hold electrode CEh2 of the hold capacitor Chd (see FIG. 18). The third conductive pattern 1310 may include an opening 1310OP having a closed shape in an area in which the third conductive pattern 1310 overlaps the first conductive pattern 1210 (see FIG. 20).

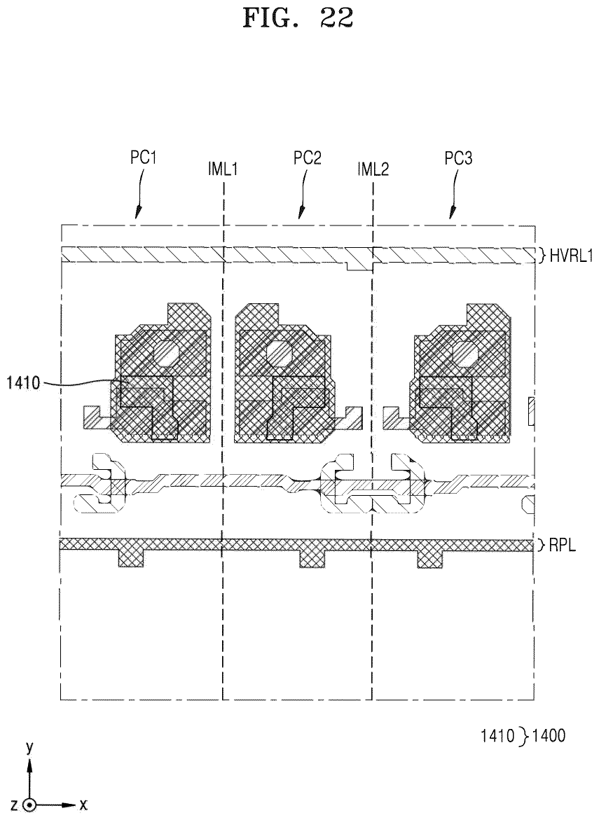

Referring to FIG. 22, a third conductive layer 1400 may be disposed on the second conductive layer 1300. The third conductive layer 1400 may include a fourth conductive pattern 1410.

The fourth conductive pattern 1410 disposed in each of the first to third pixel circuits PC1 to PC3 may have an isolated shape. The fourth conductive pattern 1410 may overlap the third conductive pattern 1310 (see FIG. 11). The fourth conductive pattern 1410 may include a first lower gate electrode G1b (see FIG. 8) of the first transistor T1 (see FIG. 18).

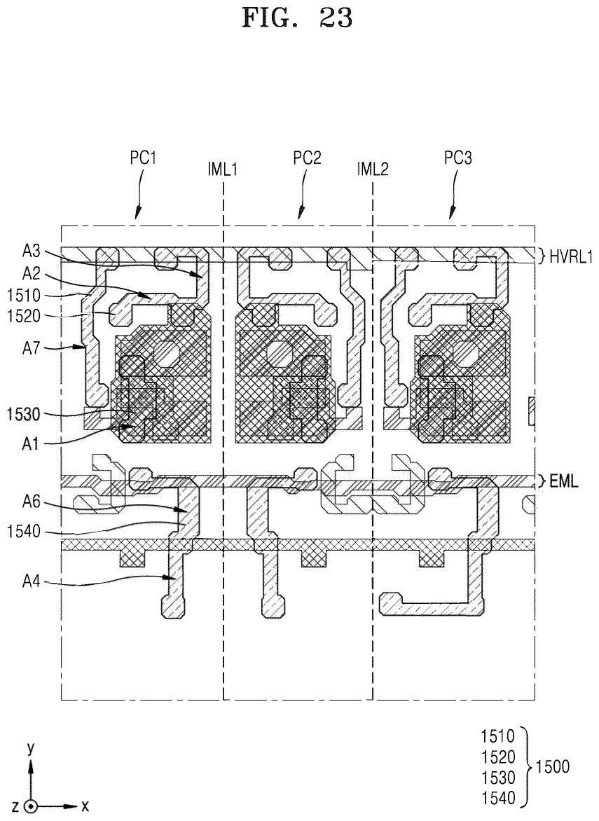

Referring to FIG. 23, an oxide semiconductor layer 1500 may be disposed on the third conductive layer 1400. The oxide semiconductor layer 1500 may include a first oxide semiconductor pattern 1510, a second oxide semiconductor pattern 1520, a third oxide semiconductor pattern 1530, and a fourth oxide semiconductor pattern 1540.

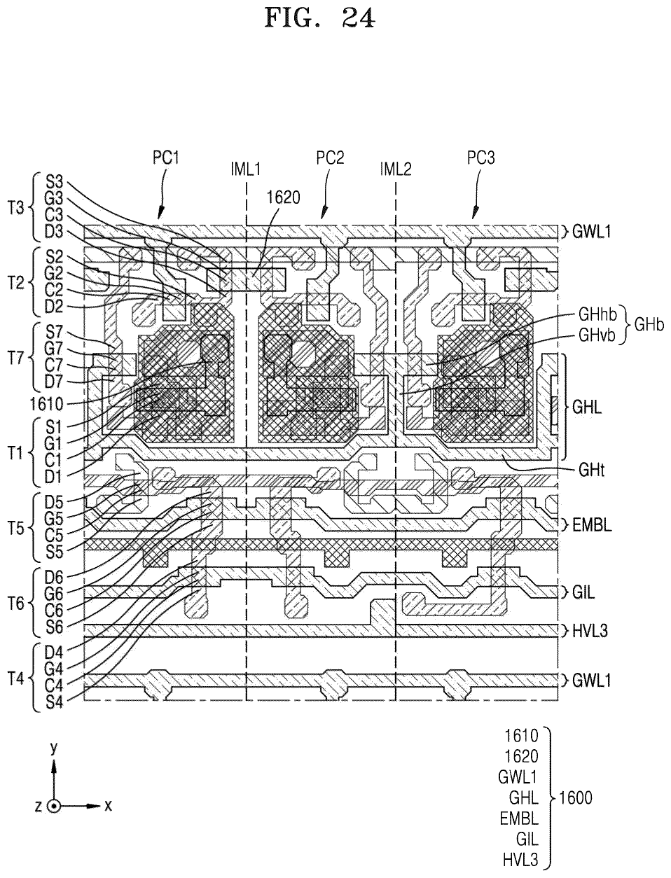

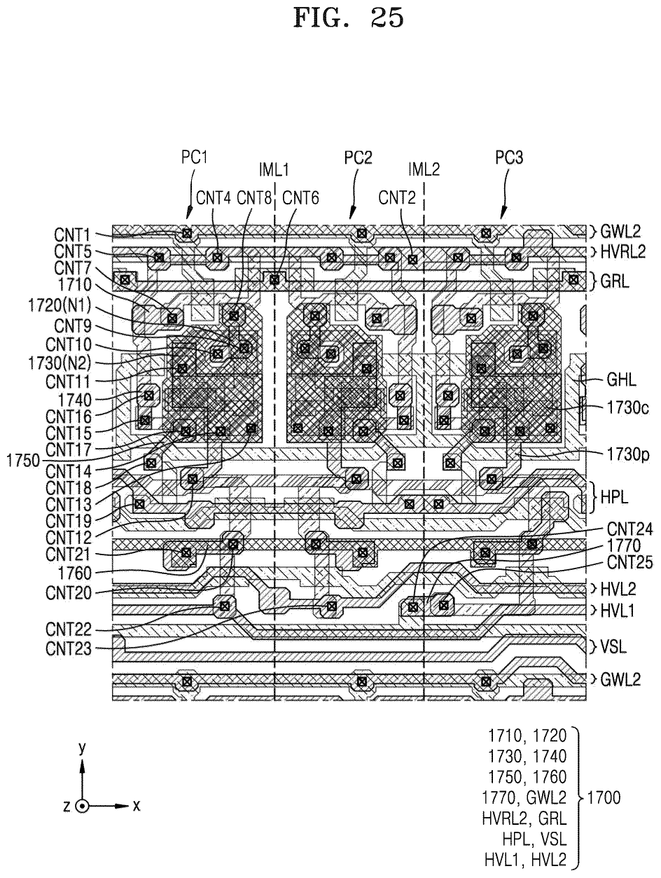

The first oxide semiconductor pattern 1510 disposed in each of the first to third pixel circuits PC1 to PC3 may have an isolated shape. The first oxide semiconductor pattern 1510 may include a seventh semiconductor layer A7 of the seventh transistor T7 (see FIG. 18). The seventh semiconductor layer A7 may overlap the hold gate line GHL (see FIG. 24) of a fourth conductive layer 1600 (see FIG. 24) described below. An end of the first oxide semiconductor pattern 1510 may be electrically connected to the hold capacitor Chd (see FIG. 18) through an eleventh conductive pattern 1740 (see FIG. 25) described below. The other end of the first oxide semiconductor pattern 1510 may overlap the first horizontal reference voltage line HVRL1 and a second horizontal reference voltage line HVRL2 (see FIG. 25) and may be electrically connected to the second horizontal reference voltage line HVRL2 (see FIG. 25).

The second oxide semiconductor pattern 1520 disposed in each of the first to third pixel circuits PC1 to PC3 may have an isolated shape. The second oxide semiconductor pattern 1520 may be bent to approximately have an “L” shape. The second oxide semiconductor pattern 1520 may include a second semiconductor layer A2 of the second transistor T2 (see FIG. 18) and a third semiconductor layer A3 of the third transistor T3 (see FIG. 18). For example, the second semiconductor layer A2 of the second transistor T2 (see FIG. 18) and the third semiconductor layer A3 of the third transistor T3 (see FIG. 18) may be integrally connected to each other. The second semiconductor layer A2 may overlap a first scan line GWL1 (see FIG. 24) described below, and the third semiconductor layer A3 may overlap a seventh conductive pattern 1620 (see FIG. 24) described below.

The third oxide semiconductor pattern 1530 disposed in each of the first to third pixel circuits PC1 to PC3 may have an isolated shape. The third oxide semiconductor pattern 1530 may have a shape extending in a second direction (e.g., a y direction). The third oxide semiconductor pattern 1530 may include a first semiconductor layer A1 of the first transistor T1 (see FIG. 18). The first semiconductor layer A1 may overlap the fourth conductive pattern 1410 (see FIG. 22) and a sixth conductive pattern 1610 (see FIG. 24) described below. The fourth conductive pattern 1410 (see FIG. 22) and the sixth conductive pattern 1610 (see FIG. 24) may form a dual gate structure of the first transistor T1 (see FIG. 18).

The fourth oxide semiconductor pattern 1540 disposed in each of the first to third pixel circuits PC1 to PC3 may have an isolated shape. The fourth oxide semiconductor pattern 1540 of each of the first and second pixel circuits PC1 and PC2 may be bent to have an inverted “L” shape. The fourth oxide semiconductor pattern 1540 of the third pixel circuit PC3 may include the same shape as the fourth oxide semiconductor pattern 1540 of the first pixel circuit PC1 and may further include a protrusion portion further extending from its end in the first direction (e.g., the x direction).

The fourth oxide semiconductor pattern 1540 may include a fourth semiconductor layer A4 and a sixth semiconductor layer A6. For example, the fourth semiconductor layer A4 and the sixth semiconductor layer A6 may be integrally connected to each other. An end of the fourth oxide semiconductor pattern 1540 may overlap the first emission control line EML. However, an end of the fourth oxide semiconductor pattern 1540 may be connected to a protrusion portion of a tenth conductive pattern 1730 (see FIG. 25) described below. The other end of the fourth oxide semiconductor pattern 1540 may overlap and be connected to a horizontal initialization voltage line HVL (see FIG. 18).

Referring to FIG. 24, the fourth conductive layer 1600 may be disposed on the oxide semiconductor layer 1500. The fourth conductive layer 1600 may include the first scan line GWL1, the hold gate line GHL, the second emission control line EMBL, an initialization gate line GIL, a third horizontal initialization voltage line HVL3, the sixth conductive pattern 1610, and a seventh conductive pattern 1620.

The first scan line GWL1 may extend in the first direction (e.g., the x direction) and may cross the first pixel circuit PC1, the second pixel circuit PC2, and the third pixel circuit PC3. The first scan line GWL1 may include a stem portion extending in the first direction (e.g., the x direction) and a branch portion protruding from the stem portion and protruding in the second direction (e.g., the y direction). The branch portion of the first scan line GWL1 may include a portion overlapping the second oxide semiconductor pattern 1520 (see FIG. 23), for example, a second gate electrode G2 of the second transistor T2.

The hold gate line GHL may include a stem portion GHt extending in the first direction (e.g., the x direction) and a branch portion GHb protruding from the stem portion GHt. The stem portion GHt of the hold gate line GHL may extend in the first direction (e.g., the x direction) and may cross the first pixel circuit PC1, the second pixel circuit PC2, and the third pixel circuit PC3. The stem portion GHT of the hold gate line GHL may cross pixel circuits disposed in the same row as the first pixel circuit PC1 and the second pixel circuit PC2.

The branch portion GHb of the hold gate line GHL may include a vertical branch portion GHvb protruding from the stem portion GHt of the hold gate line GHL and extending in the second direction (e.g., the y direction) and a horizontal branch portion GHhb protruding from the vertical branch portion GHvb and extending in the first direction (e.g., the x direction). The horizontal branch portion GHhb of the hold gate line GHL may include a portion overlapping the first oxide semiconductor pattern 1510 (see FIG. 23), for example, a seventh gate electrode G7 of the seventh transistor T7. Referring to FIGS. 23 and 24, the seventh semiconductor layer A7 of the seventh transistor T7 may include a channel area C7 overlapping the hold gate line GHL and conductive areas S7 and D7 disposed at both sides of the channel area C7, respectively. One of the conductive areas S7 and D7 may be a source area, and the other may be a drain area. The source area and the drain area may correspond to a source electrode and a drain electrode, respectively. The positions of the source area and the drain area may be exchanged according to the characteristic of a transistor.

The second emission control line EMBL may extend in the first direction (e.g., the x direction) and may cross the first pixel circuit PC1, the second pixel circuit PC2, and the third pixel circuit PC3. The second emission control line EMBL may include a portion overlapping the fourth oxide semiconductor pattern 1540 (see FIG. 23), for example, a sixth gate electrode G6 of the sixth transistor T6.

The initialization gate line GIL may extend in the first direction (e.g., the x direction) and may cross the first pixel circuit PC1, the second pixel circuit PC2, and the third pixel circuit PC3. The initialization gate line GIL may include a portion overlapping the fourth oxide semiconductor pattern 1540 (see FIG. 23), for example, a fourth gate electrode G4 of the fourth transistor T4.

The third horizontal initialization voltage line HVL3 may extend in the first direction (e.g., the x direction) and may cross the first pixel circuit PC1, the second pixel circuit PC2, and the third pixel circuit PC3. The third horizontal initialization voltage line HVL3 may be connected to the fourth oxide semiconductor pattern 1540 (see FIG. 23) of the third pixel circuit PC3 through a fourteenth conductive pattern 1770 (see FIG. 25) described below.

The sixth conductive pattern 1610 disposed in each of the first to third pixel circuits PC1 to PC3 may have an isolated shape. The sixth conductive pattern 1610 of each of the first to third pixel circuits PC1 to PC3 may include a first gate electrode G1 of the first transistor T1.

The seventh conductive pattern 1620 may have an isolated shape and may have a shape extending in the first direction (e.g., the x direction). The seventh conductive pattern 1620 may be disposed across the first and second pixel circuits PC1 and PC2 or across the third and first pixel circuits PC3 and PC1. The seventh conductive pattern 1620 of each of the first to third pixel circuits PC1 to PC3 may include a third gate electrode G3 of the third transistor T3.

Referring to FIG. 25, a fifth conductive layer 1700 may be disposed on the fourth conductive layer 1600. The fifth conductive layer 1700 may include a second scan line GWL2, the second horizontal reference voltage line HVRL2, the reference gate line GRL, a horizontal driving voltage line HPL, a first horizontal initialization voltage line HVL1, a second horizontal initialization voltage line HVL2, a common voltage line VSL, and eighth to fourteenth conductive patterns 1710, 1720, 1730, 1740, 1750, 1760, and 1770.

The second scan line GWL2 may extend in the first direction (e.g., the x direction) and may cross the first pixel circuit PC1, the second pixel circuit PC2, and the third pixel circuit PC3. The second scan line GWL2 may overlap the first scan line GWL1 (see FIG. 24) and may be electrically connected to the first scan line GWL1 (see FIG. 24) through a first contact hole CNT1.

The second horizontal reference voltage line HVRL2 may extend in the first direction (e.g., the x direction) and may cross the first pixel circuit PC1, the second pixel circuit PC2, and the third pixel circuit PC3. The second horizontal reference voltage line HVRL2 may be electrically connected to the first horizontal reference voltage line HVRL1 (see FIG. 19) through a second contact hole CNT2. Also, the second horizontal reference voltage line HVRL2 may be connected to the second oxide semiconductor pattern 1520 (see FIG. 23) through a fourth contact hole CNT4 and may be connected to the first oxide semiconductor pattern 1510 (see FIG. 23) through a fifth contact hole CNT5.

The reference gate line GRL may extend in the first direction (e.g., the x direction) and may cross the first pixel circuit PC1, the second pixel circuit PC2, and the third pixel circuit PC3. The reference gate line GRL may be electrically connected to the seventh conductive pattern 1620 (see FIG. 14) through a sixth contact hole CNT6.

The eighth conductive pattern 1710 located in each of the first to third pixel circuits PC1 to PC3 may have an isolated shape. The eighth conductive pattern 1710 may be a connection electrode connecting the second oxide semiconductor pattern 1520 (see FIG. 23) including the second semiconductor layer A2 (see FIG. 13) to the data line DL (see FIG. 18). The eighth conductive pattern 1710 may be connected to an end of the second oxide semiconductor pattern 1520 (see FIG. 23) through a seventh contact hole CNT7.

The ninth conductive pattern 1720 located in each of the first to third pixel circuits PC1 to PC3 may have an isolated shape. The ninth conductive pattern 1720 may be a connection electrode connecting the second oxide semiconductor pattern 1520 (see FIG. 23) including the second semiconductor layer A2 (see FIG. 23) and the third semiconductor layer A3 (see FIG. 23) to the sixth conductive pattern 1610 (see FIG. 24) including the first gate electrode G1 (see FIG. 24) of the first transistor T1 (see FIG. 24). For example, the ninth conductive pattern 1720 may be a first node electrode N1 connecting the first transistor T1 (see FIG. 24), the second transistor T2 (see FIG. 24), and the third transistor T3 (see FIG. 24). The ninth conductive pattern 1720 may be connected to the second oxide semiconductor pattern 1520 (see FIG. 23) through an eighth contact hole CNT8 and may be connected to the sixth conductive pattern 1610 (see FIG. 24) through a ninth contact hole CNT9. Also, the ninth conductive pattern 1720 may be electrically connected to the storage capacitor Cst (see FIG. 18). The ninth conductive pattern 1720 may be connected to the first storage electrode CEs1 (see FIG. 20) of the storage capacitor Cst (see FIG. 18) through a tenth contact hole CNT10.

The tenth conductive pattern 1730 located in each of the first to third pixel circuits PC1 to PC3 may have an isolated shape. The tenth conductive pattern 1730 may be a connection electrode connecting the third oxide semiconductor pattern 1530 (see FIG. 23) including the first semiconductor layer A1 (see FIG. 23) to the fourth oxide semiconductor pattern 1540 (see FIG. 23) including the sixth semiconductor layer A6 (see FIG. 23). For example, the tenth conductive pattern 1730 may be a second node electrode N2 connecting the first transistor T1 (see FIG. 24) to the sixth transistor T6 (see FIG. 24).

The tenth conductive pattern 1730 may include a central portion 1730c overlapping the third conductive pattern 1310 (see FIG. 21) and a protrusion portion 1730p protruding from the central portion 1730c. The protrusion portion 1730p of the tenth conductive pattern 1730 may have a shape extending from the central portion 1730c in the second direction (e.g., a-y direction). The central portion 1730c of the tenth conductive pattern 1730 may be connected to the third oxide semiconductor pattern 1530 (see FIG. 23) through an eleventh contact hole CNT11. The protrusion portion 1730p of the tenth conductive pattern 1730 may be connected to the fourth oxide semiconductor pattern 1540 (see FIG. 23) through a twelfth contact hole CNT12.

Also, the tenth conductive pattern 1730 may also be electrically connected to the storage capacitor Cst (see FIG. 18), the hold capacitor Chd (see FIG. 18), and the first lower gate electrode G1b (see FIG. 8) of the first transistor T1 (see FIG. 24). The tenth conductive pattern 1730 may be electrically connected to the third conductive pattern 1310 (see FIG. 21) including the second storage electrode CEs2 (see FIG. 21) and the second hold electrode CEh2 (see FIG. 21) through a thirteenth contact hole CNT13. The tenth conductive pattern 1730 may be electrically connected to the fourth conductive pattern 1410 (see FIG. 22) including the first lower gate electrode G1b (see FIG. 8) through a fourteenth contact hole CNT14.

The eleventh conductive pattern 1740 located in each of the first to third pixel circuits PC1 to PC3 may have an isolated shape. The eleventh conductive pattern 1740 may have a shape extending in the second direction (e.g., the y direction). The eleventh conductive pattern 1740 may be a connection electrode connecting the first hold electrode CEh1 (see FIG. 20) of the hold capacitor Chd (see FIG. 18) to the first oxide semiconductor pattern 1510 (see FIG. 23) including the seventh semiconductor layer A7 (see FIG. 23). An end of the eleventh conductive pattern 1740 may be electrically connected to the second conductive pattern 1220 (see FIG. 20) including the first hold electrode CEh1 (see FIG. 20) through a fifteenth contact hole CNT15. The other end of the eleventh conductive pattern 1740 may be electrically connected to the first oxide semiconductor pattern 1510 (see FIG. 23) through a sixteenth contact hole CNT16.

The twelfth conductive pattern 1750 located in each of the first to third pixel circuits PC1 to PC3 may have an isolated shape. The twelfth conductive pattern 1750 may have a shape extending in the first direction (e.g., the x direction). The twelfth conductive pattern 1750 may be a connection electrode connecting the third oxide semiconductor pattern 1530 (see FIG. 23) including the first semiconductor layer A1 (see FIG. 23) to the first silicon semiconductor pattern 1110 (see FIG. 19) including the fifth semiconductor layer A5 (see FIG. 19). An end of the twelfth conductive pattern 1750 may be electrically connected to the third oxide semiconductor pattern 1530 (see FIG. 23) through a seventeenth contact hole CNT17, and the other end of the twelfth conductive pattern 1750 may be electrically connected to the first silicon semiconductor pattern 1110 (see FIG. 19) through an eighteenth contact hole CNT18.

The horizontal driving voltage line HPL may extend in the first direction (e.g., the x direction) and may cross the first pixel circuit PC1, the second pixel circuit PC2, and the third pixel circuit PC3. The horizontal driving voltage line HPL may be electrically connected to the first silicon semiconductor pattern 1110 (see FIG. 19) through a nineteenth contact hole CNT19 and may transmit a driving voltage to the fifth transistor T5 (see FIG. 20).

The thirteenth conductive pattern 1760 located in each of the first to third pixel circuits PC1 to PC3 may have an isolated shape. The thirteenth conductive pattern 1760 may have a shape extending in the first direction (e.g., the x direction). The thirteenth conductive pattern 1760 may be a connection electrode connecting the fourth oxide semiconductor pattern 1540 (see FIG. 23) including the fourth semiconductor layer A4 (see FIG. 23) and the sixth semiconductor layer A6 (see FIG. 23) to the light-emitting diode LED (see FIG. 8). The thirteenth conductive pattern 1760 may be electrically connected to the fourth oxide semiconductor pattern 1540 (see FIG. 23) through a twentieth contact hole CNT20 and may be electrically connected to the repair line RPL (see FIG. 21) through a twenty-first contact hole CNT21.

The first horizontal initialization voltage line HVL1 and the second horizontal initialization voltage line HVL2 may extend in the first direction (e.g., the x direction) and may cross the first to third pixel circuits PC1 to PC3. The first horizontal initialization voltage line HVL1 may be electrically connected to the fourth oxide semiconductor pattern 1540 (see FIG. 23) of the first pixel circuit PC1 through a twenty-second contact hole CNT22, and the second horizontal initialization voltage line HVL2 may be electrically connected to the fourth oxide semiconductor pattern 1540 (see FIG. 23) of the second pixel circuit PC2 through a twenty-third contact hole CNT23.

The fourteenth conductive pattern 1770 may have an isolated shape and may be disposed on a virtual line IML2 which is an edge between the second pixel circuit PC2 and the third pixel circuit PC3. The fourteenth conductive pattern 1770 may have a shape extending in the first direction (e.g., the x direction). The fourteenth conductive pattern 1770 may be a connection electrode connecting the fourth oxide semiconductor pattern 1540 (see FIG. 23) of the third pixel circuit PC3 to the third horizontal initialization voltage line HVL3 (see FIG. 24). The fourteenth conductive pattern 1770 may be electrically connected to the third horizontal initialization voltage line HVL3 (see FIG. 24) through a twenty-fourth contact hole CNT24 and may be electrically connected to the fourth oxide semiconductor pattern 1540 (see FIG. 23) of the third pixel circuit PC3 through a twenty-fifth contact hole CNT25.

The common voltage line VSL may extend in the first direction (e.g., the x direction) and may cross the first pixel circuit PC1, the second pixel circuit PC2, and the third pixel circuit PC3.

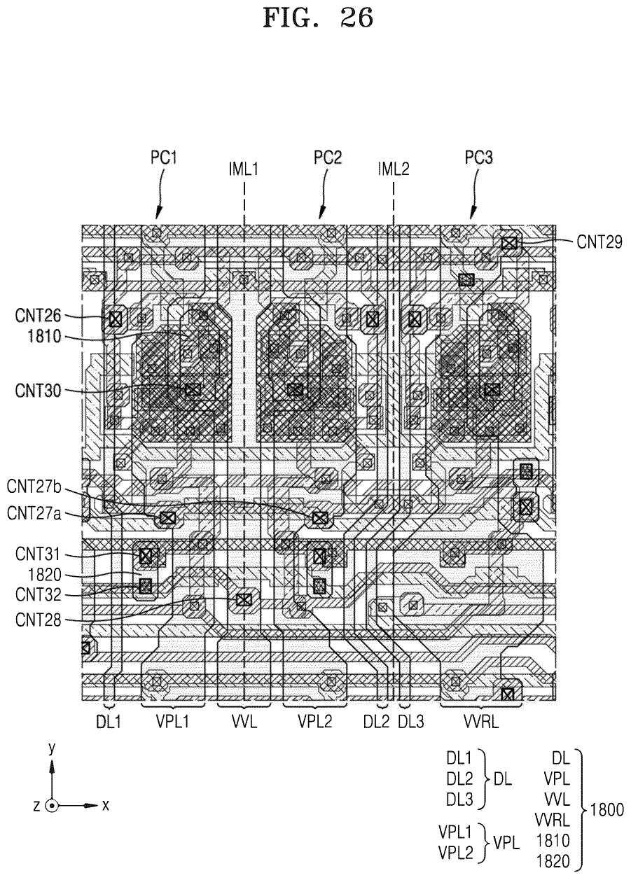

Referring to FIG. 26, a sixth conductive layer 1800 may be disposed on the fifth conductive layer 1700. The sixth conductive layer 1800 may include the data line DL, a vertical driving voltage line VPL, a vertical initialization voltage line VVL, a vertical reference voltage line VRL, a fifteenth conductive pattern 1810, and a sixteenth conductive pattern 1820.

The data line DL may extend in the second direction (e.g., the y direction). The data line DL may be electrically connected to the eighth conductive pattern 1710 (see FIG. 25) connected to the second oxide semiconductor pattern 1520 (see FIG. 23) through a twenty-sixth contact hole CNT26. A first data line DL1 may cross the first pixel circuit PC1, a second data line DL2 may cross the second pixel circuit PC2, and a third data line DL3 may cross the third pixel circuit PC3 except for a portion thereof.

The vertical driving voltage line VPL may extend in the second direction (e.g., the y direction). The vertical driving voltage line VPL may include a first vertical driving voltage line VPL1 disposed at the first pixel circuit PC1 and a second vertical driving voltage line VPL2 disposed at the second pixel circuit PC2. The first vertical driving voltage line VPL1 may be electrically connected to the horizontal driving voltage line HPL (see FIG. 25) through a twenty-seventh-1 contact hole CNT27a, and the second vertical driving voltage line VPL2 may be electrically connected to the horizontal driving voltage line HPL (see FIG. 25) through a twenty-seventh-2 contact hole CNT27b.

The vertical initialization voltage line VVL may extend in the second direction (e.g., the y direction). The vertical initialization voltage line VVL may be disposed between the first vertical driving voltage line VPL1 and the second vertical driving voltage line VPL2. The vertical initialization voltage line VVL may be electrically connected to the second horizontal initialization voltage line HVL2 (see FIG. 25) through a twenty-eighth contact hole CNT28.

The vertical reference voltage line VVRL may extend in the second direction (e.g., the y direction). The vertical reference voltage line VVRL may be disposed at the third pixel circuit PC3. The vertical reference voltage line VVRL may be electrically connected to the second horizontal reference voltage line HVRL2 (see FIG. 25) through a twenty-ninth contact hole CNT29.

Each of the fifteenth conductive pattern 1810 and the sixteenth conductive pattern 1820 may have an isolated shape. The fifteenth conductive pattern 1810 may be electrically connected to the tenth conductive pattern 1730 (see FIG. 25) through a thirtieth contact hole CNT30 and may have a shape extending in the second direction (e.g., the y direction) to cover the ninth conductive pattern 1720 (see FIG. 25). The sixteenth conductive pattern 1820 may be a connection electrode connecting the fourth oxide semiconductor pattern 1540 (see FIG. 23) to the light-emitting diode LED (see FIG. 8). The sixteenth conductive pattern 1820 may be electrically connected to the thirteenth conductive pattern 1760 (see FIG. 25) through a thirty-first contact hole CNT31 and may be electrically connected to the pixel electrode 210 (see FIG. 8) of the light-emitting diode LED (see FIG. 8) through a thirty-second contact hole CNT32.

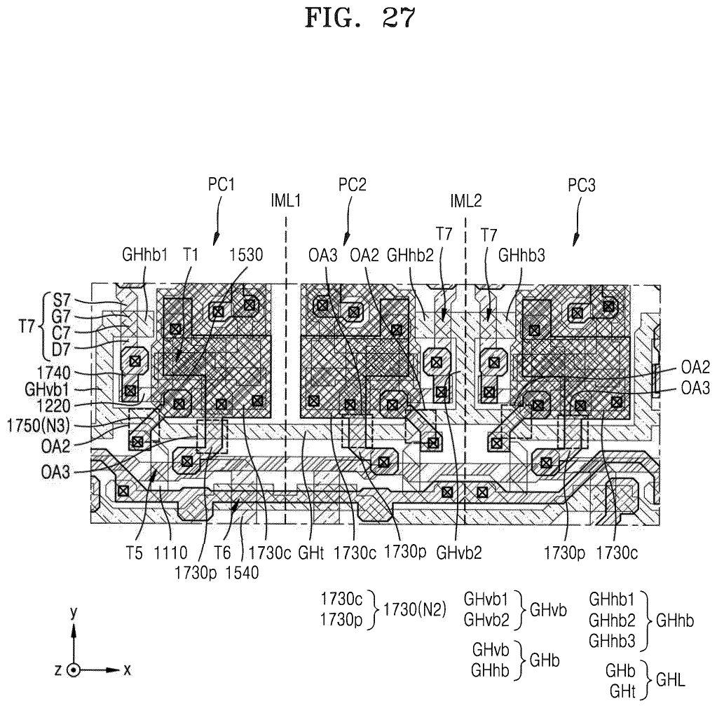

FIG. 27 is an enlarged plan view of a portion of a display panel according to an embodiment. For convenience of explanation, FIG. 27 illustrates a structure in which only the silicon semiconductor layer 1100 (see FIG. 19), the first conductive layer 1200 (see FIG. 20), the second conductive layer 1300 (see FIG. 21), the third conductive layer 1400 (see FIG. 22), the oxide semiconductor layer 1500 (see FIG. 23), the fourth conductive layer 1600 (see FIG. 24), and the fifth conductive layer 1700 (see FIG. 25) are stacked.

Referring to FIG. 27, the hold gate line GHL may include a stem portion GHt extending in a first direction (e.g., an x direction) and a branch portion GHb protruding from the stem portion GHt. The stem portion GHt of the hold gate line GHL may extend in the first direction (e.g., the x direction) and may cross the first pixel circuit PC1, the second pixel circuit PC2, and the third pixel circuit PC3. The stem portion GHT of the hold gate line GHL may cross pixel circuits disposed in the same row as the first pixel circuit PC1 and the second pixel circuit PC2.

The branch portion GHb of the hold gate line GHL may include a vertical branch portion GHvb protruding from the stem portion GHt of the hold gate line GHL and extending in a second direction (e.g., a y direction) and a horizontal branch portion GHhb protruding from the vertical branch portion GHvb and extending in the first direction (e.g., the x direction). The horizontal branch portion GHhb of the hold gate line GHL may include a portion overlapping the first oxide semiconductor pattern 1510 (see FIG. 23), for example, the seventh gate electrode G7 of the seventh transistor T7.

The vertical branch portion GHvb may include a first vertical branch portion GHvb1 protruding toward the seventh transistor T7 of the first pixel circuit PC1 and a second vertical branch portion GHvb2 protruding toward the seventh transistor T7 of the second pixel circuit PC2 and the seventh transistor T7 of the third pixel circuit PC3. The first vertical branch portion GHvb1 may be disposed at a left side of the tenth conductive pattern 1730 of the first pixel circuit PC1 in the first pixel circuit PC1. The second vertical branch portion GHvb2 may be disposed on a virtual line IML2 which is an edge between the second pixel circuit PC2 and the third pixel circuit PC3. A portion of the second vertical branch portion GHvb2 may be disposed in the region of the second pixel circuit PC2 and the remaining portions may be disposed in the region of the third pixel circuit PC3. For example, the second vertical branch portion GHvb2 may be disposed between the tenth conductive pattern 1730 of the second pixel circuit PC2 and the tenth conductive pattern 1730 of the third pixel circuit PC3.

The horizontal branch portion GHvb may include a first horizontal branch portion GHhb1 including the seventh gate electrode G7 of the first pixel circuit PC1, a second horizontal branch portion GHhb2 including the seventh gate electrode G7 of the second pixel circuit PC2, and a third horizontal branch portion GHhb3 including the seventh gate electrode G7 of the third pixel circuit PC3. The first horizontal branch portion GHhb1 may protrude from an end of the first vertical branch portion GHvb1 toward the tenth conductive pattern 1730, the second horizontal branch portion GHhb2 may protrude from an end of the second vertical branch portion GHvb2 toward the tenth conductive pattern 1730, and the third horizontal branch portion GHhb3 may protrude from an end of the second vertical branch portion GHvb2 toward the tenth conductive pattern 1730.

However, the structure of the hold gate line GHL is not necessarily limited thereto. According to an embodiment, the vertical branch portion GHvb may include a first vertical branch portion, a second vertical branch portion, and a third vertical branch portion which are protruding from the stem portion GHt and extend in the second direction (e.g., the y direction). Each of the first to third vertical branch portions may be disposed at the left side of the tenth conductive pattern 1730 of the pixel circuit corresponding thereto. Here, the first to third horizontal branch portions may be integrally connected to the first to third vertical branch portions, respectively.

A portion of the first oxide semiconductor pattern 1510, the portion overlapping the hold gate line GHL, may be the channel area C7 of the seventh transistor T7. An end of the first oxide semiconductor pattern 1510 may be connected to the second horizontal reference voltage line HVRL2 (see FIG. 25), so that the seventh transistor T7 may receive a reference voltage. The other end of the first oxide semiconductor pattern 1510 may be electrically connected to the first hold electrode CEh1 (see FIG. 20) of the hold capacitor Chd (see FIG. 18) including the second conductive pattern 1220, through the eleventh conductive pattern 1740.

According to an embodiment, the hold gate line GHL may cross between the first transistor T1 and the fifth transistor T5 in a plan view. For example, the hold gate line GHL may cross between the third oxide semiconductor pattern 1530 in which the first semiconductor layer A1 (see FIG. 23) is disposed and the first silicon semiconductor pattern 1110 in which the fifth semiconductor layer A5 (see FIG. 19) is disposed, in the plan view.

As the hold gate line GHL crosses between the first transistor T1 and the fifth transistor T5, the hold gate line GHL may overlap the connection electrode connecting the first transistor T1 to the fifth transistor T5. For example, the hold gate line GHL may include a second overlapping area OA2 overlapping the twelfth conductive pattern 1750. Here, the twelfth conductive pattern 1750 may be a third node electrode N3 connecting the first semiconductor layer A1 (see FIG. 23) with the fifth semiconductor layer A5 (see FIG. 19).

According to an embodiment, the hold gate line GHL may cross between the first transistor T1 and the sixth transistor T6 in a plan view. For example, the hold gate line GHL may cross between the third oxide semiconductor pattern 1530 in which the first semiconductor layer A1 (see FIG. 23) is disposed and the fourth oxide semiconductor pattern 1540 in which the sixth semiconductor layer A6 (see FIG. 23) is disposed, in the plan view.

As the hold gate line GHL crosses between the first transistor T1 and the sixth transistor T6, the hold gate line GHL may overlap the connection electrode connecting the first transistor T1 to the sixth transistor T6. For example, the hold gate line GHL may include a third overlapping area OA3 overlapping the protrusion portion 1730p of the tenth conductive pattern 1730. The protrusion portion 1730p of the tenth conductive pattern 1730 may be a portion protruding from the central portion 1730c in the second direction (e.g., a-y direction). Here, the tenth conductive pattern 1730 may be the second node electrode N2 connecting the first semiconductor layer A1 (see FIG. 23) to the sixth semiconductor layer A6 (see FIG. 23).

Consequently, the hold gate line GHL may include the second overlapping area OA2 overlapping the twelfth conductive pattern 1730 which is the third node electrode N3 and the third overlapping area OA3 overlapping the protrusion portion 1730p of the tenth conductive pattern 1730 which is the second node electrode N2.

The display panel, according to an embodiment, may include the seventh transistor T7 connected to the hold capacitor Chd and the hold gate line GHL, and thus, may adjust the hold capacitor Chd through a hold signal transmitted through the hold gate line GHL. Here, as illustrated in FIG. 27, when the display panel includes the seventh transistor T7 connected to the hold capacitor Chd and the hold gate line GHL, the hold capacitor Chd may be adjusted to be formed only in a data write section and a compensation section and to be blocked in an emission section. When the hold capacitor Chd is blocked in the emission section, the voltages of the second node electrode N2 and the first node electrode N1 may further be maintained to be stable, and thus, coupling of the pixel circuits may further become robust.

Also, as the hold gate line GHL extends in the first direction (e.g., the x direction), the hold gate line GHL may inevitably and partially overlap a node electrode of the first transistor T1. For example, as illustrated in FIG. 27, when the hold gate line GHL crosses between the first transistor T1 and the fifth transistor T5 and between the first transistor T1 and the sixth transistor T6, the hold gate line GHL may overlap each of the second node electrode N2 and the third node electrode N3.

As illustrated in FIG. 27, when the hold gate line GHL includes only the second overlapping area OA2 and the third overlapping area OA3, the hold gate line GHL might not overlap the first node electrode N1 (see FIG. 25). Thus, in the display panel according to an embodiment, unexpected coupling between the first node electrode N1 (see FIG. 25) and the hold gate line GHL might not occur, and thus, defects, such as an increased brightness compared to a reference brightness when a single-colored image is realized, etc. may be prevented, and a high-quality image may be realized.

According to some embodiments, a display panel and an electronic device for reducing power consumption and providing a high-quality image may be provided. The effects described above are examples, and the effects of the disclosure are not necessarily limited thereto.

It should be understood that embodiments described herein should be considered in a descriptive sense only and not necessarily for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the present disclosure.

What is claimed is:

1. A display panel, comprising:
a substrate;
a first pixel circuit disposed on the substrate and comprising a driving transistor; and
a light-emitting diode connected to the first pixel circuit,
wherein the first pixel circuit further comprises:
a first conductive pattern disposed on the substrate;
a second conductive pattern disposed on the first conductive pattern and overlapping the first conductive pattern;
a first semiconductor pattern disposed on the second conductive pattern, the first semiconductor pattern comprising a semiconductor layer of the driving transistor;
a second semiconductor pattern disposed on a same layer as the first semiconductor pattern and spaced apart from the first semiconductor pattern; and
a third conductive pattern disposed on the first semiconductor pattern and connecting the first semiconductor pattern to the second conductive pattern,
wherein the first conductive pattern is electrically connected to the second semiconductor pattern, and
wherein a portion of the second semiconductor pattern overlaps a hold gate line extending in a first direction and electrically connected to the first pixel circuit.

2. The display panel of claim 1, wherein the first conductive pattern and the second conductive pattern are included in a hold capacitor of the first pixel circuit.

3. The display panel of claim 1, further comprising a reference voltage line extending in the first direction and electrically connected to the first pixel circuit,
wherein a first end of the second semiconductor pattern is electrically connected to the first conductive pattern, and
wherein a second end of the second semiconductor pattern is electrically connected to the reference voltage line.

4. The display panel of claim 3, wherein the first pixel circuit further comprises a fourth conductive pattern disposed on a same layer as the third conductive pattern and spaced apart from the third conductive pattern, and
wherein the second semiconductor pattern is electrically connected to the first conductive pattern through the fourth conductive pattern.

5. The display panel of claim 1, wherein, with respect to a thickness direction of the substrate, the hold gate line is disposed between the first semiconductor pattern and the third conductive pattern.

6. The display panel of claim 5, wherein the hold gate line is disposed on a same layer as a gate electrode of the driving transistor.

7. The display panel of claim 1, wherein the first pixel circuit further comprises:
a third semiconductor pattern disposed on a same layer as the first semiconductor pattern and spaced apart from the first semiconductor pattern; and
a fifth conductive pattern connecting a gate electrode of the driving transistor to the third semiconductor pattern,
wherein the fifth conductive pattern is disposed on a same layer as the third conductive pattern.

8. The display panel of claim 7, further comprising:
a scan line extending in the first direction and electrically connected to the first pixel circuit; and
a data line extending in a second direction crossing the first direction and electrically connected to the first pixel circuit,
wherein a portion of the third semiconductor pattern overlaps a portion of the scan line, and
wherein an end of the third semiconductor pattern is electrically connected to the data line.

9. The display panel of claim 7, wherein, in a plan view, the hold gate line crosses between the first semiconductor pattern and the third semiconductor pattern.

10. The display panel of claim 7, wherein, in a plan view, a portion of the hold gate line overlaps the fifth conductive pattern.

11. The display panel of claim 1, wherein the first pixel circuit further comprises:
a fourth semiconductor pattern disposed between the substrate and the first conductive pattern; and
a sixth conductive pattern connecting an end of the first semiconductor pattern to the fourth semiconductor pattern,
wherein the sixth conductive pattern is disposed on a same layer as the third conductive pattern.

12. The display panel of claim 11, wherein the first semiconductor pattern comprises an oxide semiconductor material, and the fourth semiconductor pattern comprises a silicon semiconductor material.

13. The display panel of claim 11, further comprising:
a first emission control line extending in the first direction and electrically connected to the first pixel circuit; and
a driving voltage line extending in the first direction or a second direction crossing the first direction and electrically connected to the first pixel circuit,
wherein a portion of the fourth semiconductor pattern overlaps the first emission control line, and
wherein an end of the fourth semiconductor pattern is electrically connected to the driving voltage line.

14. The display panel of claim 11, wherein, in a plan view, the hold gate line crosses between the first semiconductor pattern and the fourth semiconductor pattern, and
wherein, in a plan view, a portion of the hold gate line overlaps the sixth conductive pattern.

15. The display panel of claim 1, wherein the first pixel circuit further comprises a fifth semiconductor pattern disposed on a same layer as the first semiconductor pattern and spaced apart from the first semiconductor pattern,
wherein the third conductive pattern comprises a central portion and a protrusion portion protruding from the central portion, and
wherein the protrusion portion of the third conductive pattern is electrically connected to the fifth semiconductor pattern.

16. The display panel of claim 15, further comprising a second emission control line extending in the first direction and electrically connected to the first pixel circuit,
wherein a portion of the fifth semiconductor pattern overlaps the second emission control line, and
wherein an end of the fifth semiconductor pattern is electrically connected to the light-emitting diode.

17. The display panel of claim 15, wherein, in a plan view, the hold gate line crosses between the first semiconductor pattern and the fifth semiconductor pattern, and
wherein, in a plan view, a portion of the hold gate line overlaps the protrusion portion of the third conductive pattern.

18. An electronic device comprising:
a display panel; and
a lower cover forming an exterior shape and having an opening on a front surface thereof, the opening exposing a portion of the display panel,
wherein the display panel comprises:
a substrate;
a first pixel circuit disposed on the substrate and comprising a driving transistor;
a hold gate line extending in a first direction and electrically connected to the first pixel circuit; and
a light-emitting diode connected to the first pixel circuit,
wherein the first pixel circuit further comprises:
a first conductive pattern disposed on the substrate;
a second conductive pattern disposed on the first conductive pattern and overlapping the first conductive pattern;
a first semiconductor pattern disposed on the second conductive pattern, the first semiconductor pattern comprising a semiconductor layer of the driving transistor;
a second semiconductor pattern disposed on a same layer as the first semiconductor pattern and spaced apart from the first semiconductor pattern; and
a third conductive pattern disposed on the first semiconductor pattern and connecting the first semiconductor pattern to the second conductive pattern,
wherein the first conductive pattern is electrically connected to the second semiconductor pattern, and
wherein a portion of the second semiconductor pattern overlaps the hold gate line.

19. The electronic device of claim 18, wherein the first conductive pattern and the second conductive pattern are included in a hold capacitor of the first pixel circuit.

20. The electronic device of claim 18, wherein the display panel further comprises a reference voltage line extending in the first direction and electrically connected to the first pixel circuit, and
wherein a first end of the second semiconductor pattern is electrically connected to the first conductive pattern and a second end of the second semiconductor pattern is electrically connected to the reference voltage line.
